(19) United States
(12) Patent Application Publication
(10) Pub. No.: US 2025/0391804 A1
(43) Pub. Date: Dec. 25, 2025

(54) SEMICONDUCTOR DEVICE AND ELECTRONIC DEVICE

(71) Applicant: Rohm Co., Ltd., Kyoto-shi (JP)

(72) Inventors: Shunsuke BABA, Kyoto-shi (JP); Kota ISE, Kyoto-shi (JP); Shoichi HARADA, Kyoto-shi (JP)

(21) Appl. No.: 19/305,097

(22) Filed: Aug. 20, 2025

Related U.S. Application Data
(63) Continuation of application No. PCT/JP2024/004795, filed on Feb. 13, 2024.

(30) Foreign Application Priority Data
Feb. 27, 2023 (JP) 2023-027893

(51) Int. Cl. H01L 23/00; H01L 23/495; H01L 25/07

(52) U.S. Cl. CPC H01L 24/40; H01L 23/49513; H01L 23/49562; H01L 24/41; H01L 24/48; H01L 24/73; H01L 25/074; H01L 24/32; H01L 2224/32245; H01L 2224/40249; H01L 2224/4118; H01L 2224/48247; H01L 2224/73221; H01L 2224/73263; H01L 2225/0651; H01L 2225/06524

(57) ABSTRACT

The semiconductor device includes a switching element having a first electrode, a second electrode and a third electrode, a semiconductor element having a fourth electrode and a fifth electrode, a sealing resin covering the switching element and the semiconductor element, and a plurality of terminals partially exposed from the sealing resin. The first electrode and the fourth electrode are electrically connected inside the sealing resin. The plurality of terminals include a first terminal, a second terminal, and a third terminal. The first terminal electrically conducts to the second electrode. The second terminal electrically conducts to the fifth electrode. The third terminal electrically conducts to each of the first electrode and the fourth electrode. The first terminal and the second terminal are adjacent to each other.

### TECHNICAL FIELD

The present disclosure relates to a semiconductor device and an electronic device.

### BACKGROUND ART

Conventionally, electric products, electric vehicles, and the like incorporate power supply circuits such as DC/DC converters and inverters. Such power supply circuits include switching elements such as MOSFETs (Metal Oxide Semiconductor Field Effect Transistors) and IGBTs (Insulated Gate Bipolar Transistors). For example, JP-A-2017-60404 discloses an example of a power supply circuit. The power supply circuit disclosed in JP-A-2017-60404 includes a mounting substrate, a semiconductor switching element, and two passive components. The semiconductor switching element is a MOS (Metal Oxide Semiconductor) transistor or a bipolar transistor. One of the two passive components is a diode, and the other is a capacitor. The semiconductor switching element and the two passive components (the diode and the capacitor) are disposed on the mounting substrate. In the example disclosed in JP-A-2017-60404, such a power supply circuit is used for a step-up circuit.

### BRIEF DESCRIPTION OF THE DRAWINGS

FIG. 1 is a plan view of a semiconductor device according to a first embodiment, in which a sealing resin is indicated by imaginary lines.

FIG. 2 is a plan view corresponding to FIG. 1, in which one of two conductive plates (the upper conductive plate) is omitted.

FIG. 3 is a plan view corresponding to FIG. 2, in which a switching element and a connecting member are omitted.

FIG. 4 is a plan view corresponding to FIG. 3, in which the other one of the two conductive plates (the lower conductive plate) is omitted.

FIG. 5 is a bottom view of the semiconductor device according to the first embodiment.

FIG. 6 is a front view of the semiconductor device according to the first embodiment.

FIG. 7 is a rear view of the semiconductor device according to the first embodiment.

FIG. 8 is a left-side view of the semiconductor device according to the first embodiment.

FIG. 9 is a right-side view of the semiconductor device according to the first embodiment.

FIG. 10 is a sectional view taken along line X-X in FIG. 1.

FIG. 11 is a sectional view taken along line XI-XI in FIG. 1.

FIG. 12 is a sectional view taken along line XII-XII in FIG. 1.

FIG. 13 shows an example of a circuit configuration of an electronic device that includes the semiconductor device according to the first embodiment.

FIG. 14 shows an example of plan-view layout of the electronic device that includes the semiconductor device according to the first embodiment.

FIG. 15 is a view corresponding to FIG. 14, in which the semiconductor device, the capacitor, the inductor and the drive circuit are indicated by imaginary lines.

FIG. 16 is a plan view showing a semiconductor device according to a variation of the first embodiment, in which the sealing resin is indicated by imaginary lines.

FIG. 17 is a plan view corresponding to FIG. 16, in which one of two conductive plates (the upper conductive plate) is omitted.

FIG. 18 is a plan view corresponding to FIG. 17, in which the semiconductor element is omitted.

FIG. 19 is a plan view corresponding to FIG. 18, in which the other one of the two conductive plates (the lower conductive plate) is omitted.

FIG. 20 is a bottom view of a semiconductor device according to a variation of the first embodiment.

FIG. 21 is a sectional view taken along line XXI-XXI in FIG. 16.

FIG. 22 is a sectional view taken along line XXII-XXII in FIG. 16.

FIG. 23 is a plan view of a semiconductor device according to a second embodiment, in which a sealing resin is indicated by imaginary lines.

FIG. 24 is a plan view corresponding to FIG. 23, in which one of two conductive plates (the upper conductive plate) is omitted.

FIG. 25 is a plan view corresponding to FIG. 24, in which the semiconductor element is omitted.

FIG. 26 is a plan view corresponding to FIG. 25, in which the other one of the two conductive plates (the lower conductive plate) is omitted.

FIG. 27 is a bottom view of the semiconductor device according to the second embodiment.

FIG. 28 is a sectional view taken along line XXVIII-XXVIII in FIG. 23.

FIG. 29 is a sectional view taken along line XXIX-XXIX in FIG. 23.

FIG. 30 shows an example of a circuit configuration of an electronic device that includes the semiconductor device according to the second embodiment.

FIG. 31 shows an example of plan-view layout of the electronic device that includes the semiconductor device according to the second embodiment.

FIG. 32 is a view corresponding to FIG. 31, in which the semiconductor device, the capacitor, the inductor and the drive circuit are indicated by imaginary lines.

FIG. 33 is a plan view of a semiconductor device according to a variation of the second embodiment, in which the sealing resin is indicated by imaginary lines.

FIG. 34 is a plan view corresponding to FIG. 33, in which one of three conductive plates (the upper conductive plate) is omitted.

FIG. 35 is a plan view corresponding to FIG. 34, in which the switching element is omitted.

FIG. 36 is a plan view corresponding to FIG. 35, in which other conductive plates (including a lower conductive plate) are omitted.

FIG. 37 is a sectional view taken along line XXXVII-XXXVII in FIG. 33.

FIG. 38 is a sectional view taken along line XXXVIII-XXXVIII in FIG. 33.

FIG. 39 is a sectional view taken along line XXXIX-XXXIX in FIG. 33.

FIG. 40 is a plan view of a semiconductor device according to a third embodiment, in which a sealing resin is indicated by imaginary lines.

FIG. 41 is a plan view corresponding to FIG. 40, in which two conductive plates are omitted.

FIG. 42 is a bottom view of the semiconductor device according to the third embodiment.

FIG. 43 is a sectional view taken along line XLIII-XLIII in FIG. 40.

FIG. 44 is a sectional view taken along line XLIV-XLIV in FIG. 40.

FIG. 45 is a sectional view taken along line XLV-XLV in FIG. 40.

FIG. 46 is a plan view of a semiconductor device according to a variation of the third embodiment, in which the sealing resin is indicated by imaginary lines.

FIG. 47 is a plan view corresponding to FIG. 46, in which a conductive plate is omitted.

FIG. 48 is a bottom view of a semiconductor device according to a variation of the third embodiment.

FIG. 49 is a sectional view taken along line XLIX-XLIX in FIG. 46.

FIG. 50 is a sectional view taken along line L-L in FIG. 46.

FIG. 51 is a sectional view taken along line LI-LI in FIG. 46.

FIG. 52 is a plan view of a semiconductor device according to a fourth embodiment, in which a sealing resin is indicated by imaginary lines.

FIG. 53 is a plan view corresponding to FIG. 52, in which two conductive plates are omitted.

FIG. 54 is a bottom view of a semiconductor device according to a fourth embodiment.

FIG. 55 is a sectional view taken along line LV-LV in FIG. 52.

FIG. 56 is a sectional view taken along line LVI-LVI in FIG. 52.

FIG. 57 is a sectional view taken along line LVII-LVII in FIG. 52.

FIG. 58 is a plan view of a semiconductor device according to a variation of the fourth embodiment, in which the sealing resin is indicated by imaginary lines.

FIG. 59 is a plan view corresponding to FIG. 58, in which a conductive plate is omitted.

FIG. 60 is a bottom view of a semiconductor device according to a variation of the fourth embodiment.

FIG. 61 is a sectional view taken along line LXI-LXI in FIG. 58.

FIG. 62 is a sectional view taken along line LXII-LXII in FIG. 58.

FIG. 63 is a sectional view taken along line LXIII-LXIII in FIG. 58.

FIG. 64 is a plan view of a semiconductor device according to a variation, in which a sealing resin and one of two conductive plates (the upper conductive plate) are omitted.

FIG. 65 is a plan view of a semiconductor device according to another variation, in which a sealing resin and one of two conductive plates (the upper conductive plate) are omitted.

FIG. 66 shows an example of plan-view layout of the electronic device that includes the semiconductor device of FIG. 64.

FIG. 67 shows an example of plan-view layout of the electronic device that includes the semiconductor device of FIG. 65.

FIG. 68 is a plan view of a semiconductor device according to another variation, in which a sealing resin and one of two conductive plates (the upper conductive plate) are omitted.

FIG. 69 is a plan view of a semiconductor device according to another variation, in which a sealing resin and one of two conductive plates (the upper conductive plate) are omitted.

FIG. 70 is a plan view of a semiconductor device according to another variation.

FIG. 71 is a sectional view taken along line LXXI-LXXI in FIG. 70.

### DETAILED DESCRIPTION OF EMBODIMENTS

Preferred embodiments of the semiconductor device and the electronic device according to the present disclosure are described below with reference to the accompanying drawings. Hereinafter, the elements that are identical or similar are given the same reference numerals, and redundant explanations are omitted. In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Likewise, the expression “An object A is located on an object B” implies the situation where, unless otherwise specifically noted, “the object A is located on the object B, in contact with the object B”, and “the object A is located on the object B, with something else interposed between the object A and the object B”. Further, the expression “An object A overlaps with an object B as viewed in a certain direction” implies the situation where, unless otherwise specifically noted, “the object A overlaps with the entirety of the object B”, and “the object A overlaps with a part of the object B”. Still further, the expression “An object A (or its material) contains a certain material C” includes the situation where “the object A (or its material) is made of the material C” and the situation where “the main component of the object A (or its material) is the material C”.

### First Embodiment

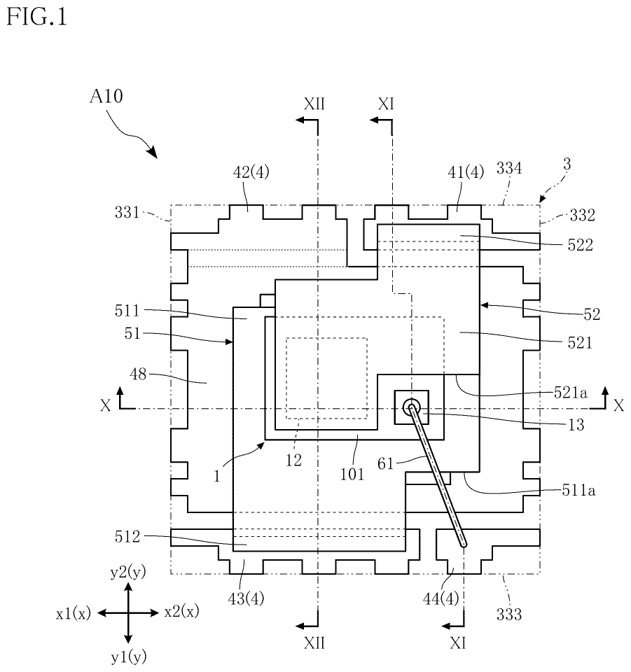

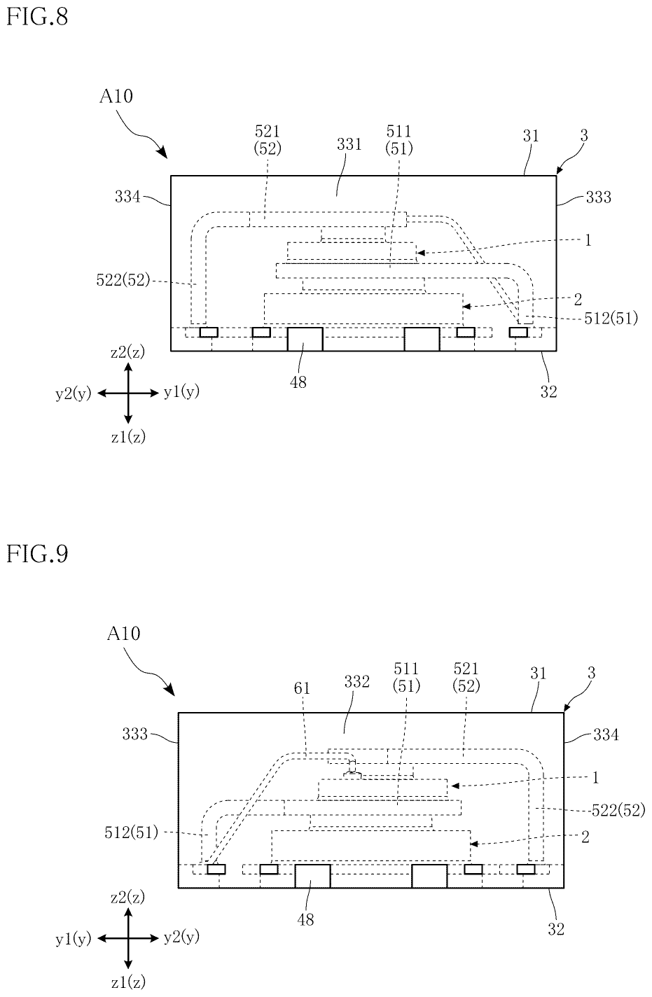

FIGS. 1 to 12 show a semiconductor device A10 according to a first embodiment. The semiconductor device A10 includes a switching element 1, a semiconductor element 2, a sealing resin 3, a plurality of terminals 4, a die pad 48, two conductive plates 51 and 52, a connecting member 61, and a plurality of bonding materials 71 to 76.

In the description given below, reference will be made to the thickness direction z, the first direction y, and the second direction x, which are orthogonal to each other. As an example, the thickness direction z corresponds to the thickness direction of the semiconductor device A10. The first direction y is orthogonal to the thickness direction z. The second direction x is orthogonal to the thickness direction z and the first direction y. In the present disclosure, the terms such as “upper”, “lower”, “upward”, “downward”, “upper surface”, and “lower surface” indicate the relative positional relationship of parts or the like in the thickness direction z, and do not necessarily define the relationship with respect to the direction of gravity.

The semiconductor device A10 is of a type that is surface-mounted on a circuit board (the mounting substrate 9 described later) in an electric device, an electric vehicle, or the like. The semiconductor device A10 is used, for example, in a DC/DC converter. As shown in FIGS. 1 to 5, the semiconductor device A10 is rectangular as viewed in the thickness direction z. The size of the semiconductor device A10 as viewed in the thickness direction z is not limited, but may be, for example, 3.3 mm square. The thickness (the dimension in the thickness direction z) of the semiconductor device A10 is not limited, but may be, for example, 1.5 mm.

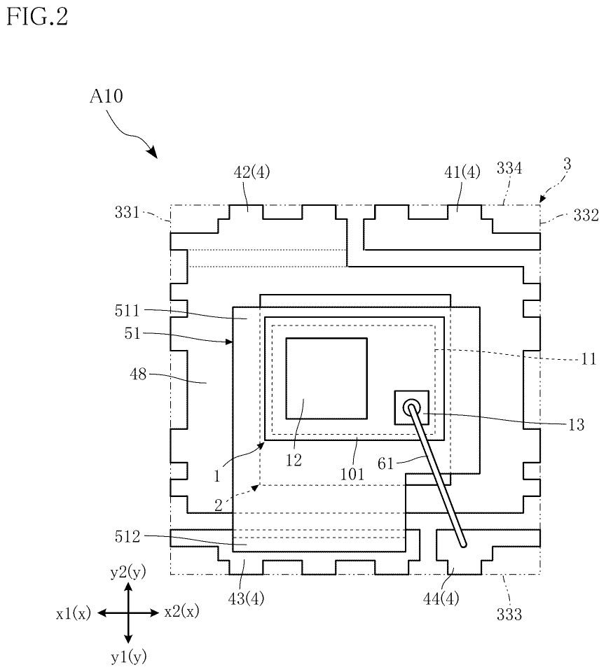

The switching element 1 is, for example, a MOSFET. The switching element 1 may not be a MOSFET but may be other transistors such as a field-effect transistor including a MISFET (Metal-Insulator-Semiconductor FET) and a HEMT (High Electron Mobility Transistor) or a bipolar transistor such as an IGBT. The switching element 1 may be a thyristor rather than a transistor. As shown in FIG. 2, the switching element 1 is rectangular as viewed in the thickness direction z. The size of the switching element 1 as viewed in the thickness direction z is not limited, but for example, the long side may be 1.6 mm, and the short side may be 1.1 mm. In semiconductor device A10, the long side is along the second direction x, and the short side is along the first direction y, as shown in FIGS. 1 and 2. The thickness (the dimension in the thickness direction z) of the switching element 1 is not limited, but may be, for example, 0.15 mm.

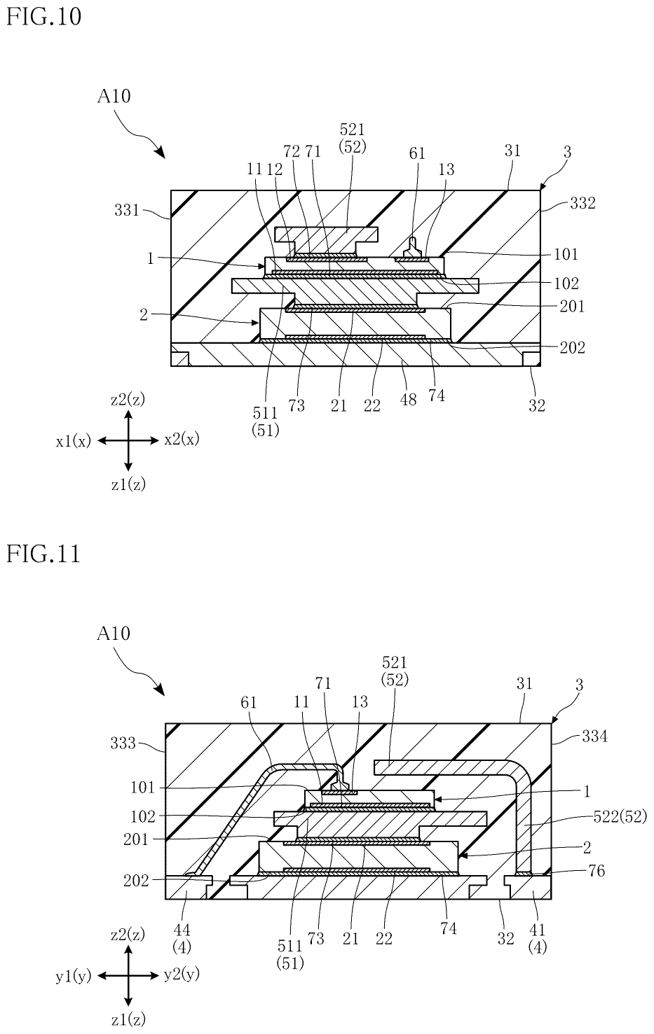

The switching element 1 has an element obverse surface 101 and an element reverse surface 102. As shown in FIGS. 10 to 12, the element obverse surface 101 and the element reverse surface 102 are spaced apart from each other in the thickness direction z. In the semiconductor device A10, the element obverse surface 101 faces upward (the z2 side) in the thickness direction z, and the element reverse surface 102 faces downward (the z1 side) in the thickness direction z.

The switching element 1 has a plurality of electrodes 11, 12, and 13. The electrode 11 is disposed on the element reverse surface 102 as shown in FIGS. 10 to 12, and the two electrodes 12 and 13 are disposed on the element obverse surface 101 as shown in FIG. 10. In the example where the switching element 1 is a MOSFET, the electrode 11 is the drain, the electrode 12 is the source, and the electrode 13 is the gate. In the case where the switching element 1 is another transistor, the drain, the source and the gate of the MOSFET may be replaced with corresponding electrodes of that transistor. (For example, when an IGBT is used as the switching element 1, the electrode 11 corresponds to the collector, the electrode 12 corresponds to the emitter, and the electrode 13 corresponds to the base.) The switching element 1 conducts a current between the electrode 11 and the electrode 12 in response to a drive signal (the gate signal) inputted to the electrode 13. The electrode 11 is an example of the “first electrode”, the electrode 12 is an example of the “second electrode”, and the electrode 13 is an example of the “third electrode”.

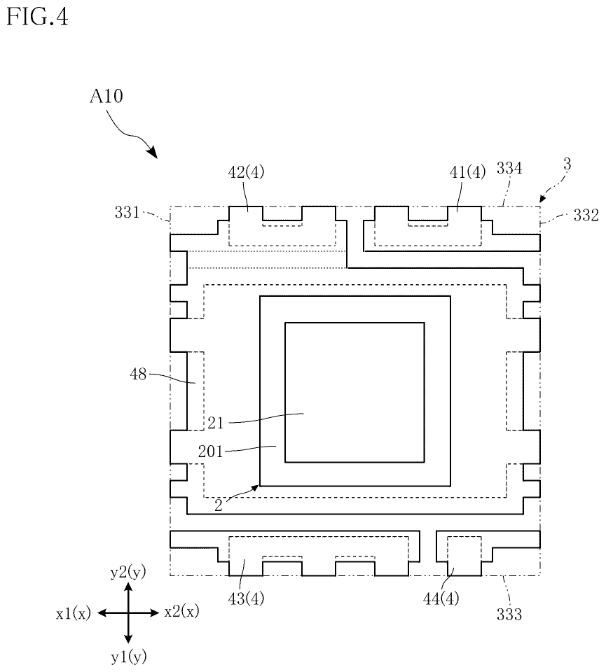

The semiconductor element 2 is, for example, a Schottky barrier diode (SBD). The semiconductor element 2 may be a diode other than a SBD. As shown in FIG. 4, the semiconductor element 2 is rectangular as viewed in the thickness direction z. The size of the semiconductor element 2 as viewed in the thickness direction z is not limited, but may be, for example, 1.7 mm square. Thus, in the illustrated example, the semiconductor element 2 is larger than the switching element 1 as viewed in the thickness direction z. The thickness (the dimension in the thickness direction z) of the semiconductor element 2 is not limited, but may be, for example, 0.26 mm. Thus, in the illustrated example, the semiconductor element 2 is thicker than the switching element 1. The size relationship between the switching element 1 and the semiconductor element 2 is changed as appropriate in accordance with the specifications of the semiconductor device A10 (the respective specifications of the switching element 1 and the semiconductor element 2).

The semiconductor element 2 has an element obverse surface 201 and an element reverse surface 202. As shown in FIGS. 10 to 12, the element obverse surface 201 and the element reverse surface 202 are spaced apart from each other in the thickness direction z. In the semiconductor device A10, the element obverse surface 201 faces upward (the z2 side) in the thickness direction z, and the element reverse surface 202 faces downward (the z1 side) in the thickness direction z.

The semiconductor element 2 has a plurality of electrodes 21 and 22. As shown in FIGS. 10 to 12, the electrode 21 is disposed on the element obverse surface 201, and the electrode 22 is disposed on the element reverse surface 202. In the example where the semiconductor element 2 is an SBD, the electrode 21 is the anode, and the electrode 22 is the cathode. In the semiconductor element 2, when a forward voltage is applied between the electrode 21 and the electrode 22, a forward current flows from the electrode 21 to the electrode 22. The electrode 21 is an example of the “fourth electrode”, and the electrode 22 is an example of the “fifth electrode”.

In the present embodiment, the switching element 1 and the semiconductor element 2 overlap with each other as viewed in the thickness direction z. As shown in FIGS. 10 to 12, the semiconductor element 2 is disposed on the lower side (the z1 side) in the thickness direction z of the switching element 1.

As understood from the configuration detailed later, in the semiconductor device A10, the electrode 11 (the drain) of the switching element 1 and the electrode 21 (the anode) of the semiconductor element 2 are electrically connected to each other inside the sealing resin 3. The semiconductor device A10, together with the inductor L1 described later, forms a step-up circuit.

The sealing resin 3 covers the switching element 1 and the semiconductor element 2. The sealing resin 3 covers a portion of each terminal 4, a portion of the die pad 48, the two conductive plates 51 and 52, the connecting member 61, and the bonding materials 71 to 76. The sealing resin 3 is rectangular as viewed in the thickness direction z. The sealing resin 3 may include an insulating resin. The insulating resin is, for example, an epoxy resin.

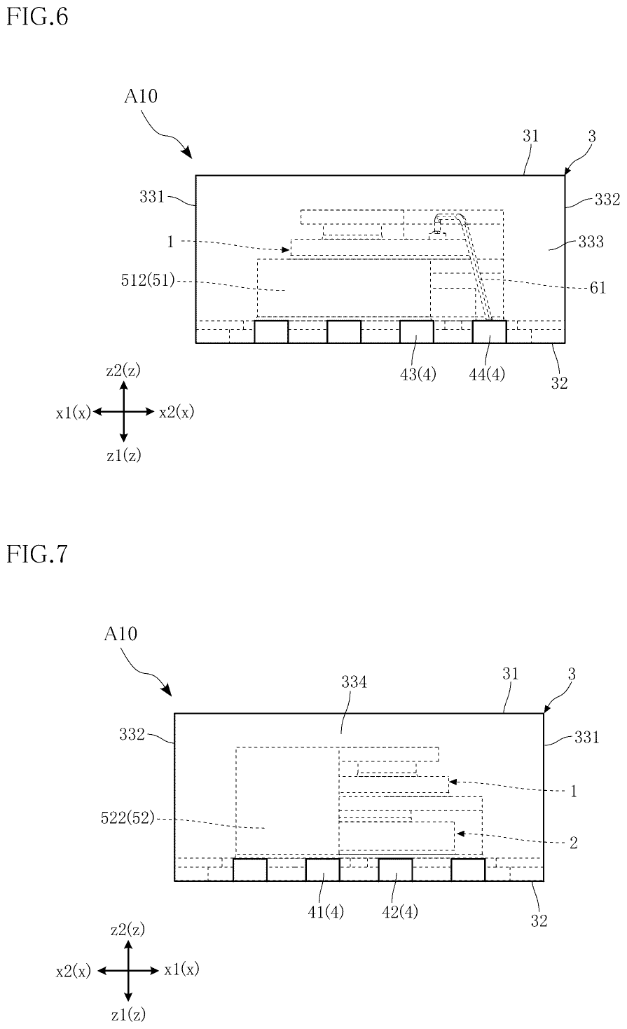

The sealing resin 3 has a resin obverse surface 31, a resin reverse surface 32, and a plurality of resin side surfaces 331 to 334. As shown in FIGS. 6 to 12, the resin obverse surface 31 and the resin reverse surface 32 are spaced apart from each other in the thickness direction z. The resin obverse surface 31 faces the z2 side in the thickness direction z, and the resin reverse surface 32 faces the z1 side in the thickness direction z. The resin obverse surface 31 and the resin reverse surface 32 are flat. The resin side surfaces 331 to 334 are located between the resin obverse surface 31 and the resin reverse surface 32 in the thickness direction z and connected to the resin obverse surface 31 and the resin reverse surface 32. As shown in FIGS. 1 to 7 and 10, the two resin side surfaces 331 and 332 are spaced apart from each other in the second direction x. The resin side surface 331 faces the x1 side in the second direction x, and the resin side surface 332 faces the x2 side in the second direction x. As shown in FIGS. 1 to 5, 8, 9, 11 and 12, the two resin side surfaces 333 and 334 are spaced apart from each other in the first direction y. The resin side surface 333 faces the y1 side in the first direction y, and the resin side surface 334 faces the y2 side in the first direction y. The resin side surfaces 331 to 334 are flat.

Each terminal 4 is partially exposed from the sealing resin 3. Each terminal 4 contains, for example, copper. The terminals 4 are made of, for example, a lead frame. The terminals 4 include a first terminal 41, a second terminal 42, a third terminal 43, and a fourth terminal 44.

The first terminal 41 electrically conducts to the electrode 12 (the source). The second terminal 42 electrically conducts to the electrode 22 (the cathode). The third terminal 43 electrically conducts to the electrode 11 (the drain) and the electrode 21 (the anode). Thus, the third terminal 43 is a common terminal for the electrode 11 and the electrode 21. The fourth terminal 44 electrically conducts to the electrode 13 (the gate).

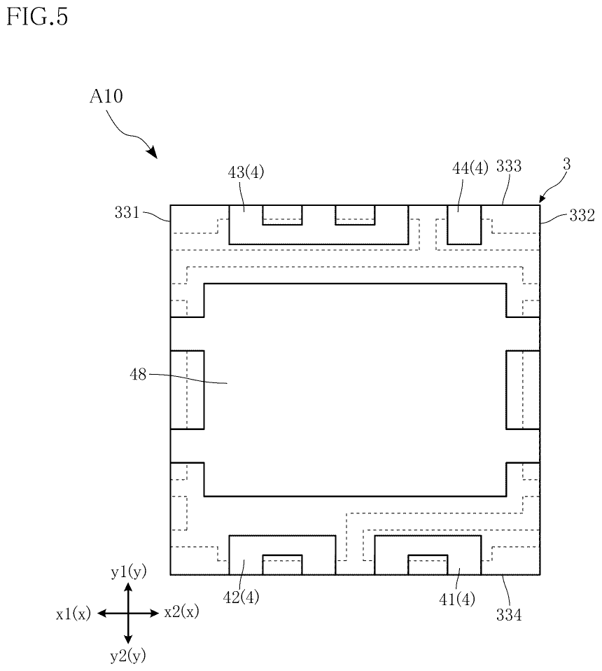

As shown in FIGS. 1 to 5, the first terminal 41 and the second terminal 42 are adjacent to each other in the second direction x. In the illustrated example, the first terminal 41 is located on the x2 side in the second direction x of the second terminal 42. Unlike this example, the first terminal 41 may be disposed on the x1 side in the second direction x of the second terminal 42. The first terminal 41 and the second terminal 42 are disposed on the y2 side in the first direction y with respect to the die pad 48. As shown in FIGS. 5 and 7, each of the first terminal 41 and the second terminal 42 is partially exposed at the resin reverse surface 32 and the resin side surface 334.

As shown in FIGS. 1 to 5, the third terminal 43 and the fourth terminal 44 are adjacent to each other in the second direction x. In the illustrated example, the fourth terminal 44 is located on the x2 side in the second direction x of the third terminal 43. Unlike this example, the fourth terminal 44 may be located on the x1 side in the second direction x of the third terminal 43. The third terminal 43 and the fourth terminal 44 are disposed on the y1 side in the first direction y with respect to the die pad 48. As shown in FIGS. 5 and 6, each of the third terminal 43 and the fourth terminal 44 is partially exposed at the resin reverse surface 32 and the resin side surface 333. The third terminal 43 overlaps with the second terminal 42 as viewed in the first direction y. The fourth terminal 44 overlaps with the first terminal 41 as viewed in the first direction y.

The die pad 48 supports the switching element 1 and the semiconductor element 2. As shown in FIGS. 10 to 12, on the die pad 48, the semiconductor element 2 is mounted and the electrode 22 (the cathode) is bonded. As shown in FIG. 4, the second terminal 42 is connected to the die pad 48. The second terminal 42 and the die pad 48 are integrally formed. Thus, the second terminal 42 electrically conducts to the electrode 22 (the cathode) via the die pad 48. The shape of the die pad 48 as viewed in the thickness direction z is not limited to the illustrated example.

The two conductive plates 51 and 52 are made of a metal material. The metal material may include, for example, copper. The two conductive plates 51 and 52 are not limited to ones made of a metal material, and may be made of any material that conducts electricity. The two conductive plates 51 and 52 are covered with the sealing resin 3.

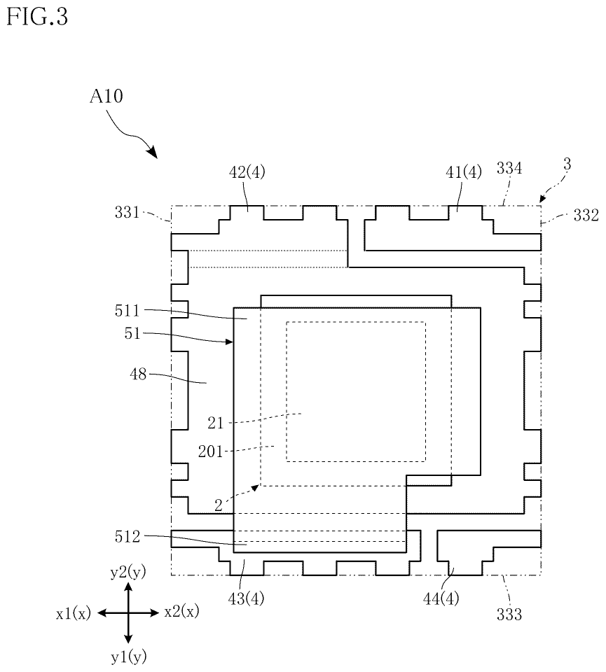

As shown in FIGS. 3 and 12, the conductive plate 51 includes a bond portion 511 and an extension portion 512. The bond portion 511 and the extension portion 512 are integrally formed. The bond portion 511 is sandwiched between the switching element 1 and the semiconductor element 2. The bond portion 511 is bonded to the electrode 11 (the drain) and the electrode 21 (the anode). The bond portion 511 is disposed on the lower side (the z1 side) in the thickness direction z with respect to the switching element 1 and on the upper side (the z2 side) with respect to the semiconductor element 2. The bond portion 511 extends along a plane orthogonal to the thickness direction z. As shown in FIGS. 10 to 12, the bond portion 511 partially projects downward (to the z1 side) in the thickness direction z. In the present embodiment, the projecting portion is bonded to the electrode 21. Unlike this example, the bond portion 511 may be partially bent downward (to the z1 side) in the thickness direction z, and the bent portion may be bonded to the electrode 21. The extension portion 512 is bonded to the third terminal 43. The extension portion 512 extends from the bond portion 511 downward (to the z1 side) in the thickness direction z. The conductive plate 51 electrically connects the third terminal 43 to each of the electrode 11 and the electrode 21.

As shown in FIGS. 1 and 10 to 12, the conductive plate 52 includes a bond portion 521 and an extension portion 522. The bond portion 521 and the extension portion 522 are integrally formed. The bond portion 521 is disposed on the upper side (the z2 side) in the thickness direction z with respect to the switching element 1. The conductive plate 52 is bonded to the electrode 12 (the source) of the switching element 1. The bond portion 521 extends along a plane orthogonal to the thickness direction z. As shown in FIGS. 10 and 12, the bond portion 521 partially projects downward (to the z1 side) in the thickness direction z. In the present embodiment, the projecting portion is bonded to the electrode 12. Unlike this example, the bond portion 521 may be partially bent downward (to the z1 side) in the thickness direction z, and the bent portion may be bonded to the electrode 12. The bond portion 521 is formed with a cutout 521a. Due to the presence of the cutout 521a, the electrode 13 of the switching element 1 does not overlap with the conductive plate 52 as viewed in the thickness direction z. To improve heat dissipation, the upper surface of the bond portion 521 (the surface facing the z2 side in the thickness direction z) may be exposed from the resin obverse surface 31 of the sealing resin 3. The extension portion 522 extends from the bond portion 521 downward (to the z1 side) in the thickness direction z. The conductive plate 52 electrically connects the first terminal 41 and the electrode 12.

The connecting member 61 electrically connects two mutually separated parts. In the illustrated example, the connecting member 61 is a bonding wire. The constituent material of the connecting member 61 is not limited, but includes, for example, gold, aluminum, silver or copper. As shown in FIG. 11, the connecting member 61 is bonded to the electrode 13 (the gate) and the fourth terminal 44. Thus, the fourth terminal 44 electrically conducts to the electrode 13 via the connecting member 61.

Each of the bonding materials 71 to 76 conductively bonds two parts. The bonding materials 71 to 76 may be, for example, solder. The bonding materials 71 to 76 may be sintered metal or metal paste rather than solder. In FIGS. 1 to 5, illustration of the bonding materials 71 to 76 is omitted.

The bonding material 71 bonds the electrode 11 (the drain) of the switching element 1. In the semiconductor device A10, as shown in FIGS. 10 to 12, the bonding material 71 is interposed between the electrode 11 and the conductive plate 51 (the bond portion 511) to conductively bond these.

The bonding material 72 bonds the electrode 12 (the source) of the switching element 1. In the semiconductor device A10, as shown in FIGS. 10 and 12, the bonding material 72 is interposed between the electrode 12 and the conductive plate 52 (the bond portion 521) to conductively bond these.

The bonding material 73 bonds the electrode 21 (the anode) of the semiconductor element 2. In the semiconductor device A10, as shown in FIGS. 10 to 12, the bonding material 73 is interposed between the electrode 21 and the conductive plate 51 (the bond portion 511) to conductively bond these.

The bonding material 74 bonds the electrode 22 (the cathode) of the semiconductor element 2. In the semiconductor device A10, as shown in FIGS. 10 to 12, the bonding material 74 is interposed between the electrode 22 and the die pad 48 to conductively bond these.

The bonding material 75 bonds the conductive plate 51 (the extension portion 512). In the semiconductor device A10, as shown in FIG. 12, the bonding material 75 is interposed between the conductive plate 51 (the extension portion 512) and the third terminal 43 to conductively bond these.

The bonding material 76 bonds the conductive plate 52 (the extension portion 522). In the semiconductor device A10, as shown in FIG. 11, the bonding material 76 is interposed between the conductive plate 52 (the extension portion 522) and the first terminal 41 to conductively bond these.

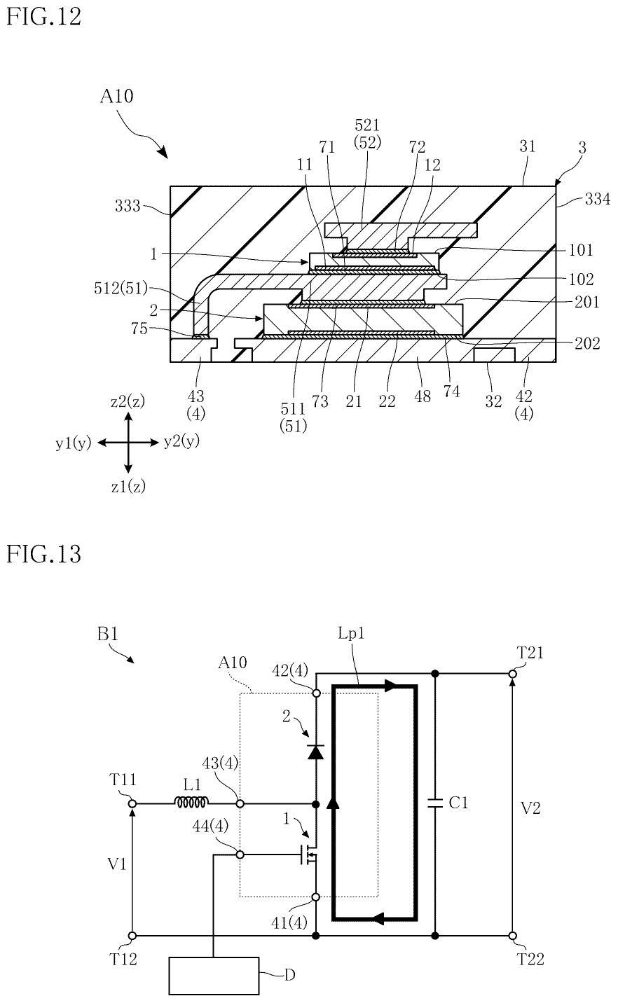

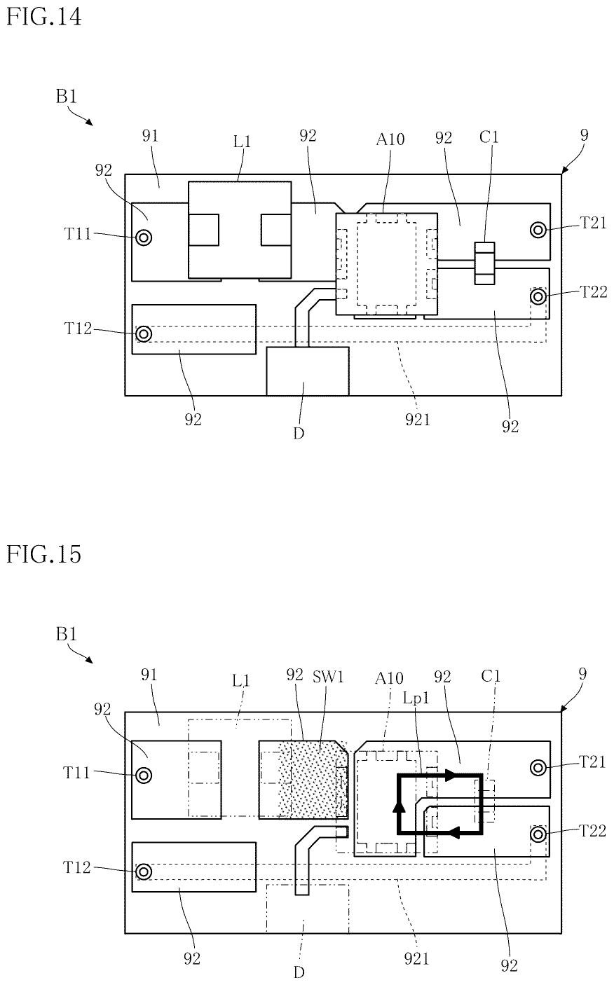

FIGS. 13 to 15 show an electronic device B1 that includes the semiconductor device A10. As shown in these figures, the electronic device B1 includes a mounting substrate 9, a capacitor C1, an inductor L1 and a drive circuit D, in addition to the semiconductor device A10.

As shown in FIG. 13, in the electronic device B1, the drain (the electrode 11) of the switching element 1 and the anode (the electrode 21) of the semiconductor element 2 are electrically connected to each other in the semiconductor device A10. The connection point of these electrically conducts to the third terminal 43. The inductor L1 is connected between the third terminal 43 and the input terminal T11. One of the electrodes of the capacitor C1 is electrically connected to the second terminal 42 of the semiconductor device A10, and the other electrode of the capacitor C1 is electrically connected to the first terminal 41 of the semiconductor device A10. That is, the capacitor C1 is connected to the cathode (the electrode 22) of the semiconductor element 2 and the source (the electrode 12) of the switching element 1. The capacitor C1 is connected to a pair of output terminals T21 and T22. The capacitor C1 functions as an output capacitor disposed on the output side of the semiconductor device A10. When the electronic device B1 (the switching element 1 and the semiconductor element 2) is energized, the potential of the second terminal 42 is higher than that of the first terminal 41, and the semiconductor element 2 is connected to the higher potential side than the switching element 1. In the example shown in FIG. 13, the electronic device B1 forms a step-up circuit (a step-up chopper circuit). The electronic device B1 increases the voltage V1 applied to the pair of input terminals T11 and T12 to voltage V2 by the switching operation of the switching element 1. Then, the increased voltage V2 is outputted from the pair of output terminals T21 and T22. The input terminal T12 and the output terminal T22 may be, for example, grounded.

The drive circuit D generates a drive signal for the switching element 1 and outputs the drive signal to the gate (the electrode 13) of the switching element 1. The drive circuit D is provided, for example, by an integrated circuit (IC).

The mounting substrate 9 may be mounted in a module of an electric product, an electric vehicle, or the like. The mounting substrate 9 may be, for example, a printed circuit board. The mounting substrate 9 may be a semiconductor substrate, a glass substrate, or a resin substrate, rather than a printed circuit board. The mounting substrate 9 includes a base 91 and a wiring pattern 92.

The base 91 supports the semiconductor device A10, the capacitor C1, the inductor L1, and the drive circuit D. When the mounting substrate 9 is a printed circuit board, the base 91 is made of a glass epoxy resin. The wiring pattern 92 is formed on the base 91. The constituent material of the wiring pattern 92 is not limited, and may include copper, for example. The constituent material of the wiring pattern 92 is not limited to those containing copper, and may be those containing gold, silver, or aluminum, for example. The wiring pattern 92 electrically connects the semiconductor device A10, the capacitor C1, the inductor L1 and the drive circuit D such that the electronic device B1 has the circuit configuration shown in FIG. 13. In the illustrated example, the wiring pattern 92 includes a reverse-surface wiring 921. The reverse-surface wiring 921 electrically conducts to the wiring pattern 92 formed on the upper surface of the base 91 through, for example, a through-via penetrating the base 91. Instead of the reverse-surface wiring 921, a wiring passing inside the base 91 may be provided. The wiring pattern 92 may connect the input terminal T12 and the output terminal T22 without including the reverse-surface wiring 921.

The effects and advantages of the semiconductor device A10 and the electronic device B1 are as follows.

In the semiconductor device A10, the electrode 11 of the switching element 1 and the electrode 21 of the semiconductor element 2 are electrically connected to each other inside the sealing resin 3. In the semiconductor device A10, the electrode 11 is the drain, and the electrode 21 is the anode. With such a configuration, the conduction distance between the electrode 11 and the electrode 21 can be made shorter than when the switching element 1 and the semiconductor element 2 are provided by separate discrete components. With such a shortened conduction distance, when the electrode 11 and the electrode 21 are connected to the inductor LI to form a step-up circuit by using the semiconductor device A10, the wiring area of the switching node (see SW 1 in FIG. 15) can be reduced. Reducing the wiring area of the switching node is effective in reducing noise. Therefore, the semiconductor device A10 can reduce noise.

In the semiconductor device A10, the first terminal 41 and the second terminal 42 are adjacent to each other. The first terminal 41 electrically conducts to the electrode 12 of the switching element 1, and the second terminal 42 electrically conducts to the electrode 22 of the semiconductor element 2. In the semiconductor device A10, the electrode 12 is the source, and the electrode 22 is the cathode. With such a configuration, the separation distance between the first terminal 41 and the second terminal 42 can be made shorter than when the first terminal 41 and the second terminal 42 are disposed on opposite side surfaces of the sealing resin 3 (e.g., the resin side surface 333 and the resin side surface 334). With such a shortened separation distance, when the electrode 12 and the electrode 22 are connected to the capacitor C1 to form a step-up circuit by using the semiconductor device A10, the distance of the current loop Lp1 (see FIGS. 13 and 15) through the capacitor C1 can be shortened. Shortening the distance of the current loop Lp1 is effective in reducing noise. Therefore, the semiconductor device A10 can reduce noise.

In the semiconductor device A10, the switching element 1 and the semiconductor element 2 overlap with each other as viewed in the thickness direction z. In the present configuration, the switching element 1 and the semiconductor element 2 are stacked in the thickness direction z. Thus, the area of the semiconductor device A10 as viewed in the thickness direction z can be reduced.

In the semiconductor device A10, the switching element 1 is disposed on the upper side (the z2 side) in the thickness direction z with respect to the semiconductor element 2. The semiconductor element 2 is larger than the switching element 1 as viewed in the thickness direction z. With such a configuration, when the switching element 1 and the semiconductor element 2 are stacked, the one (the switching element 1 in the semiconductor device A10) on the upper side (the z2 side) in the thickness direction z can be stably placed. This prevents the switching element 1 from tilting or tipping over during manufacturing, thereby suppressing manufacturing defects in the semiconductor device A10. Thus, the semiconductor device A10 can have improved manufacturing quality.

In the semiconductor device A10, the first terminal 41 and the second terminal 42 are exposed from the resin side surface 334, and the third terminal 43 and the fourth terminal 44 are exposed from the resin side surface 333. With such a configuration, it is possible to secure an appropriate area for each of the first first terminal 41, the second terminal 42, and the third terminal 43. The main current (the current corresponding to the power supply voltage) in the step-up circuit, for example, flows through the first terminal 41, the second terminal 42, and the third terminal 43, and the allowable current of the semiconductor device A10 reduces with the reduction in the areas of the first terminal 41, the second terminal 42, and the third terminal 43. Therefore, the semiconductor device A10 can suppress reduction in the allowable current.

Other embodiments and variations of the semiconductor device and electronic device of the present disclosure are described below. Various parts of the embodiments and variations may be selectively used in any appropriate combination as long as it is technically compatible.

### Variation of the First Embodiment:

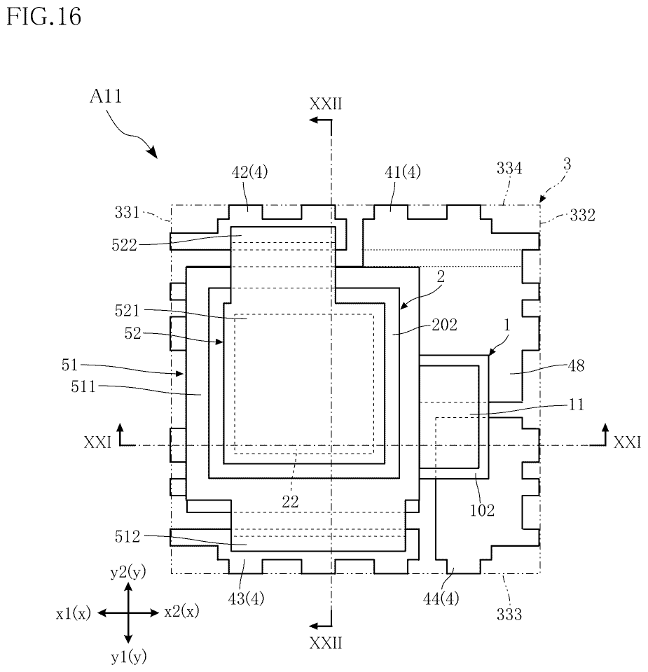

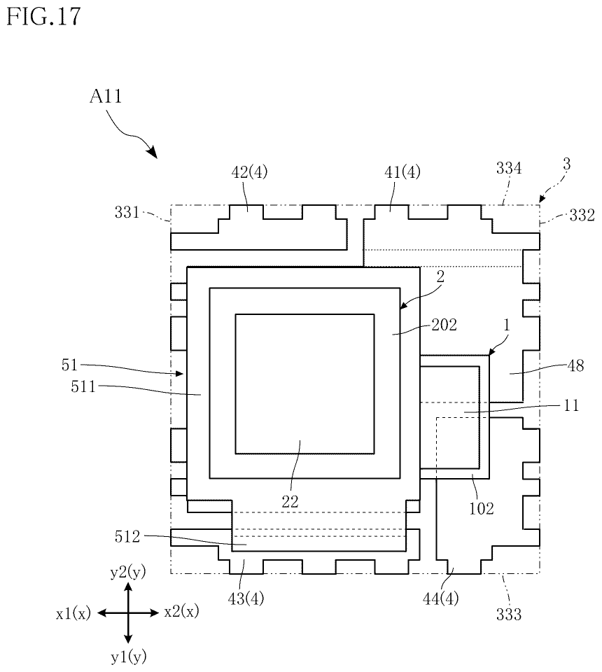

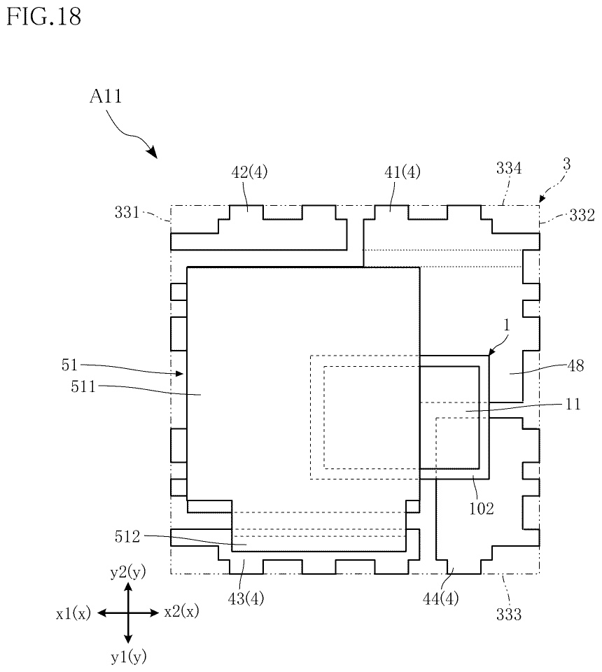

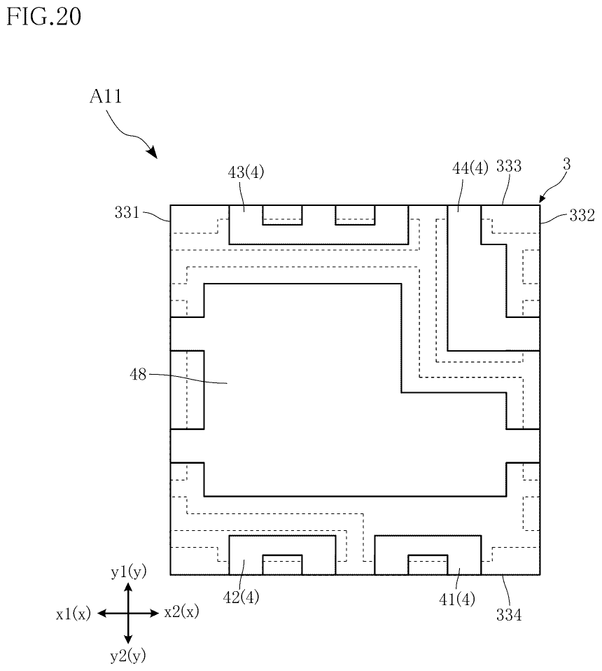

FIGS. 16 to 22 show a semiconductor device A11 according to a variation of the first embodiment. The semiconductor device A11 differs from the semiconductor device A10 in the following points. First, the switching element 1 is disposed on the z2 side in the thickness direction z of the conductive plate 51 (the bond portion 511), and the semiconductor element 2 is disposed on the z1 side in the thickness direction z of the conductive plate 51 (the bond portion 511). Second, in the semiconductor device A11, the switching element 1 is disposed with the element obverse surface 101 facing downward (the z1 side) in the thickness direction z. Thirdly, in the semiconductor device A11, the semiconductor element 2 is disposed with the element obverse surface 201 facing downward (the z1 side) in the thickness direction z. As with the semiconductor device A10, the semiconductor device A11 is incorporated in the electronic device B1 as a part of a step-up circuit (see FIGS. 13 to 15).

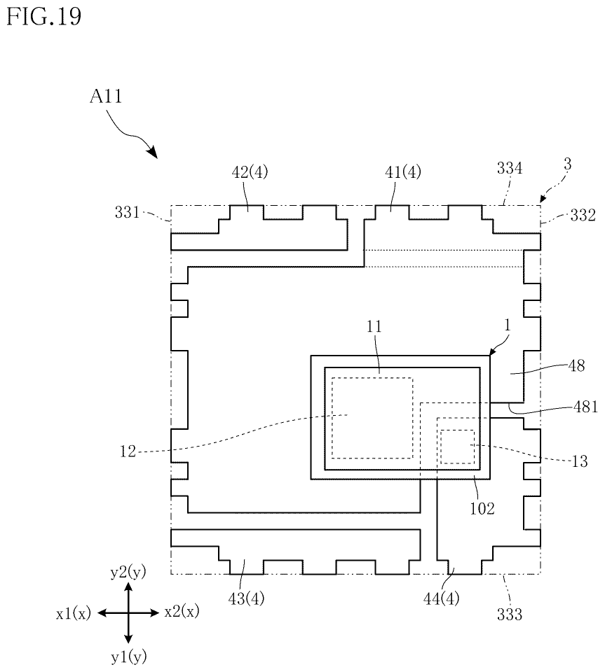

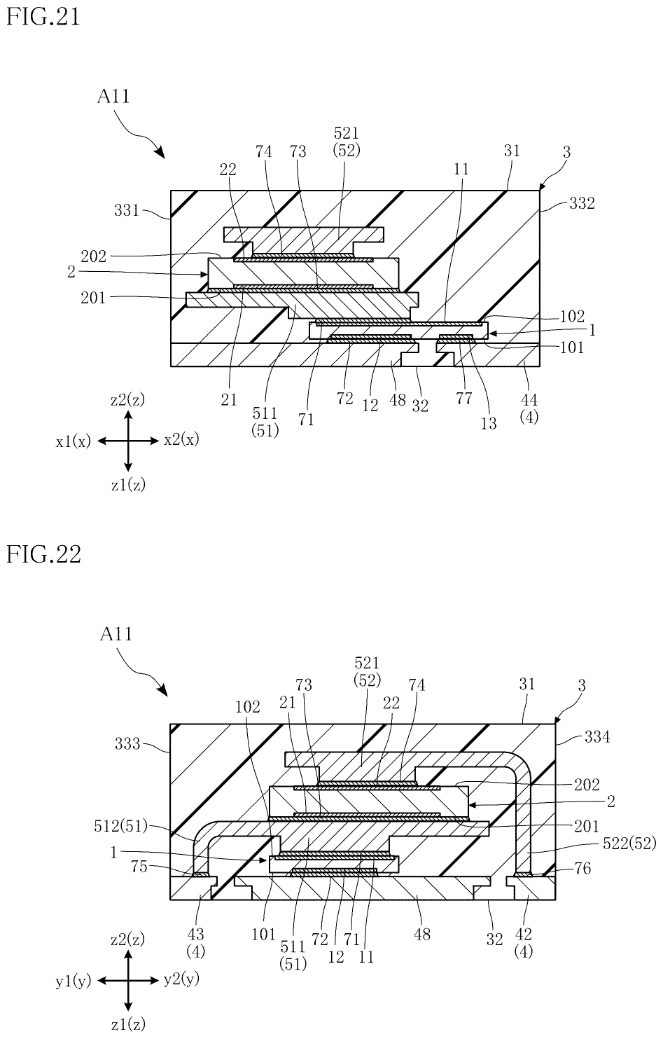

In the semiconductor device A11, the electrode 13 (the gate) of the switching element 1 is bonded to the fourth terminal 44, as shown in FIG. 21. In the semiconductor device A11, the die pad 48 is formed with a cutout 481 as shown in FIG. 19. Due to the presence of the cutout 481, the fourth terminal 44 is extended to the area that overlaps with the electrode 13 of the switching element 1 as viewed in the thickness direction z. This allows the electrode 13 of the switching element 1 to be bonded to the fourth terminal 44. In this way, the fourth terminal 44 is electrically connected to the electrode 13 by directly bonding the electrode 13 to the fourth terminal 44, so that the semiconductor device A11 does not include the connecting member 61. The electrode 12 (the source) of the switching element 1 is bonded to the die pad 48. Thus, as shown in FIGS. 21 and 22, the switching element 1 is flip-chip mounted to bridge over the die pad 48 and the fourth terminal 44. The electrode 11 (the drain) of the switching element 1 is bonded to the conductive plate 51 (the bond portion 511). Thus, the third terminal 43 electrically conducts to the electrode 11 via the conductive plate 51.

In the semiconductor device A11, the second terminal 42 is not connected to the die pad 48, and the first terminal 41 is connected to the die pad 48, as shown in FIG. 19. The first terminal 41 and the die pad 48 are integrally formed. Thus, the first terminal 41 electrically conducts to the electrode 22 (the source) via the die pad 48.

In the semiconductor device A11, as shown in FIGS. 21 and 22, the element obverse surface 201 of the semiconductor element 2 faces the conductive plate 51 (the bond portion 511), and the electrode 21 (the anode) of the semiconductor element 2 is bonded to the conductive plate 51 (the bond portion 511). Thus, the third terminal 43 electrically conducts to the electrode 21 via the conductive plate 51. Since the third terminal 43 electrically conducts to the electrode 11 (the drain) via the conductive plate 51 as mentioned before, the third terminal 43 is a common terminal for the electrode 11 (drain) and the electrode 21 (the anode). The element reverse surface 202 of the semiconductor element 2 faces the conductive plate 52 (the bond portion 521), and the electrode 22 (the cathode) of the semiconductor element 2 is bonded to the conductive plate 52 (the bond portion 521). Thus, the second terminal 42 electrically conducts to the electrode 22 via the conductive plate 52.

In the semiconductor device A11, the bonding material 72 is interposed between the electrode 12 (the source) and the die pad 48 to conductively bond these as shown in FIGS. 21 and 22. The bonding material 74 is interposed between the electrode 22 (the cathode) and the conductive plate 52 (the bond portion 521) to conductively bond these. The bonding material 76 is interposed between the conductive plate 52 (the extension portion 522) and the second terminal 42 to conductively bond these.

The semiconductor device A11 includes a bonding material 77 in addition to the bonding materials 71 to 76. The bonding material 77 bonds the electrode 13 (the gate). As shown in FIG. 21, the bonding material 77 is interposed between the electrode 13 and the fourth terminal 44 to conductively bond these. In FIGS. 16 to 19, illustration of the bonding materials 71 to 77 is omitted.

In the semiconductor device A11, the electrode 11 (the drain) of the switching element 1 and the electrode 21 (the anode) of the semiconductor element 2 are electrically connected to each other inside the sealing resin 3, as with in the semiconductor device A10. Therefore, the semiconductor device A11 can reduce noise, as with the semiconductor device A10. Further, in the semiconductor device A11, the first terminal 41, which electrically conducts to the electrode 12 (the source) of the switching element 1, and the second terminal 42, which electrically conducts to the electrode 22 (the cathode) of the semiconductor element 2, are adjacent to each other, as with in the semiconductor device A10. Therefore, the semiconductor device A11 can further reduce noise, as with the semiconductor device A10. Additionally, the semiconductor device A11 has a configuration in common with the semiconductor device A10, thereby achieving the same effect as the semiconductor device A10.

In the semiconductor device A11, the switching element 1 is disposed with the element obverse surface 101 facing the z1 side in the thickness direction z. In the present configuration, the switching element 1 is flip-chip mounted. Therefore, the semiconductor device A11 does not include the connecting member 61. Thus, as compared with the semiconductor device A10, the semiconductor device A11 can omit the step of forming the connecting member 61 (wire bonding step).

In the semiconductor device A11, the switching element 1 is mounted on the die pad 48. The electrode 12 of the switching element 1 is bonded to the die pad 48. In the present embodiment, the electrode 12 is the source. The semiconductor device A11 is used in a step-up circuit as with the semiconductor device A10, and the electrode 12 of the switching element 1 may be grounded. Therefore, the electrode 12 of the switching element 1 is connected to the ground of the mounting substrate 9 via the die pad 48. This is effective in improving the heat dissipation of the semiconductor device A11. That is, the semiconductor device A11 can improve heat dissipation more than the semiconductor device A10.

### Second Embodiment

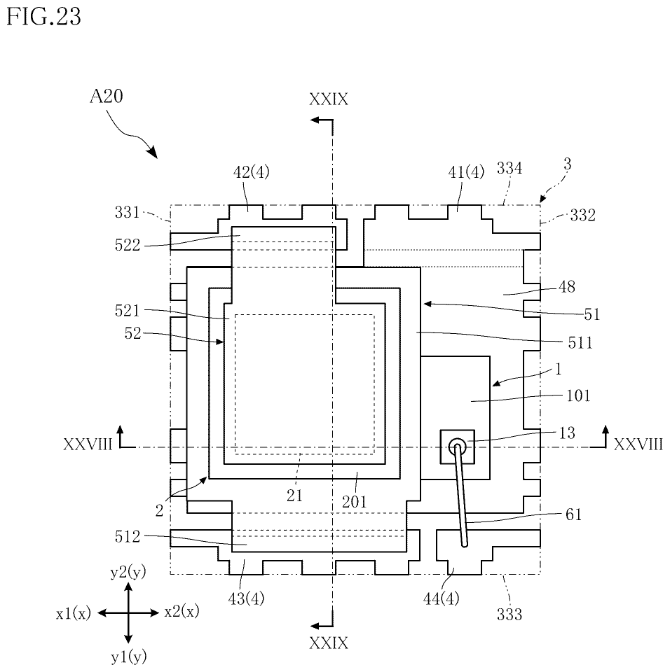

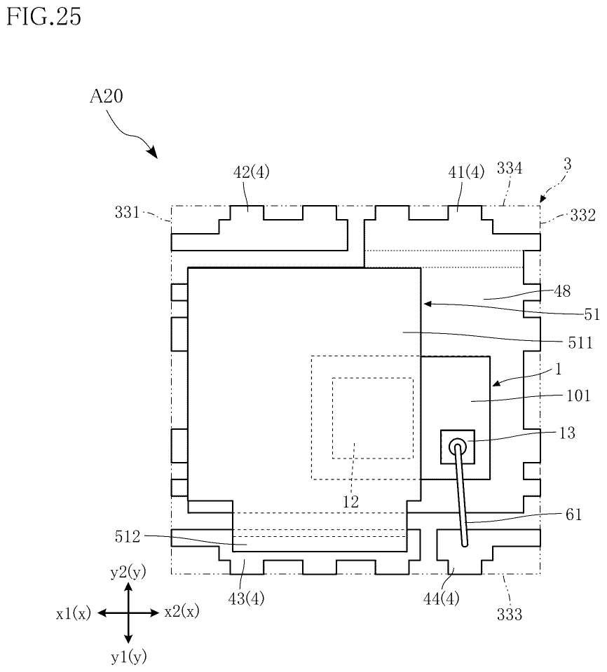

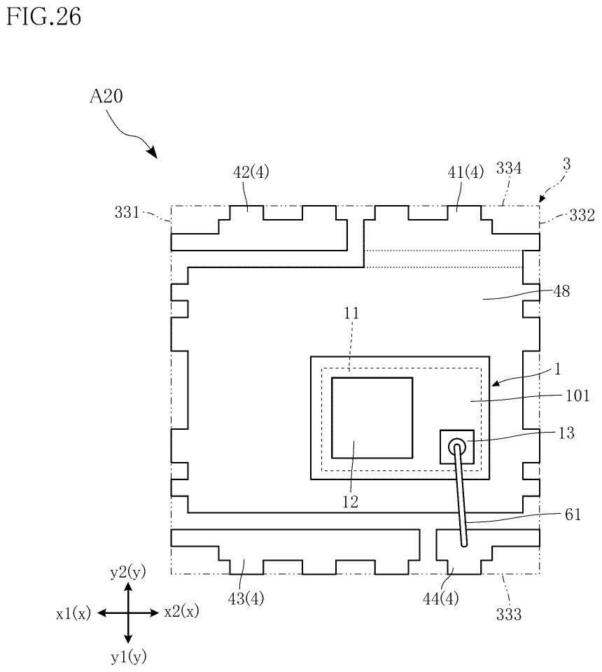

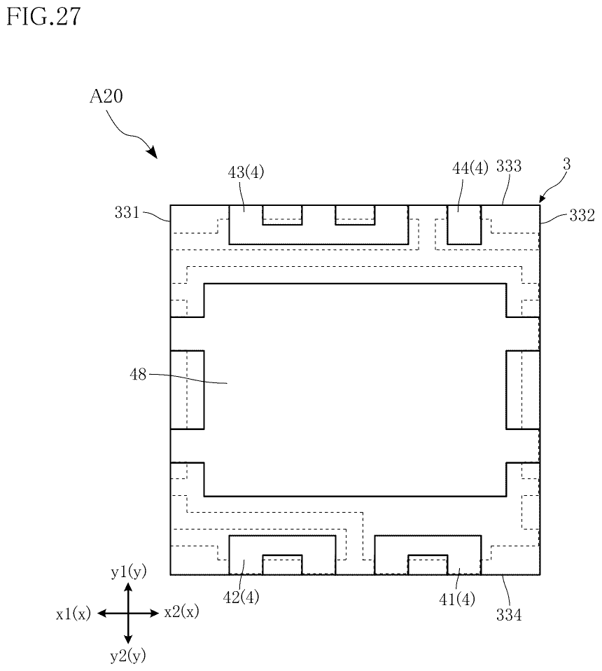

FIGS. 23 to 29 show a semiconductor device A20 according to a second embodiment. The semiconductor device A20 differs from the semiconductor device A10 in the following points. First, the first terminal 41 electrically conducts to the electrode 11 (the drain) of the switching element 1, rather than the electrode 12 (the source) of the switching element 1. Second, the second terminal 42 electrically conducts to the electrode 21 (the anode) of the semiconductor element 2, rather than the electrode 22 (the cathode) of the semiconductor element 2. Thirdly, the third terminal 43 electrically conducts to the electrode 12 (the source) of the switching element 1 and the electrode 22 (the cathode) of the semiconductor element 2, rather than the electrode 11 (the drain) of the switching element 1 and the electrode 21 (the anode) of the semiconductor element 2. As understood from the configuration detailed later, the electrode 11 (the drain) is an example of the “second electrode”, the electrode 12 (the source) is an example of the “first electrode”, and the electrode 13 (the gate) is an example of the “third electrode”. The electrode 21 (the anode) is an example of the “fifth electrode”, and the electrode 22 (the cathode) is an example of the “fourth electrode”.

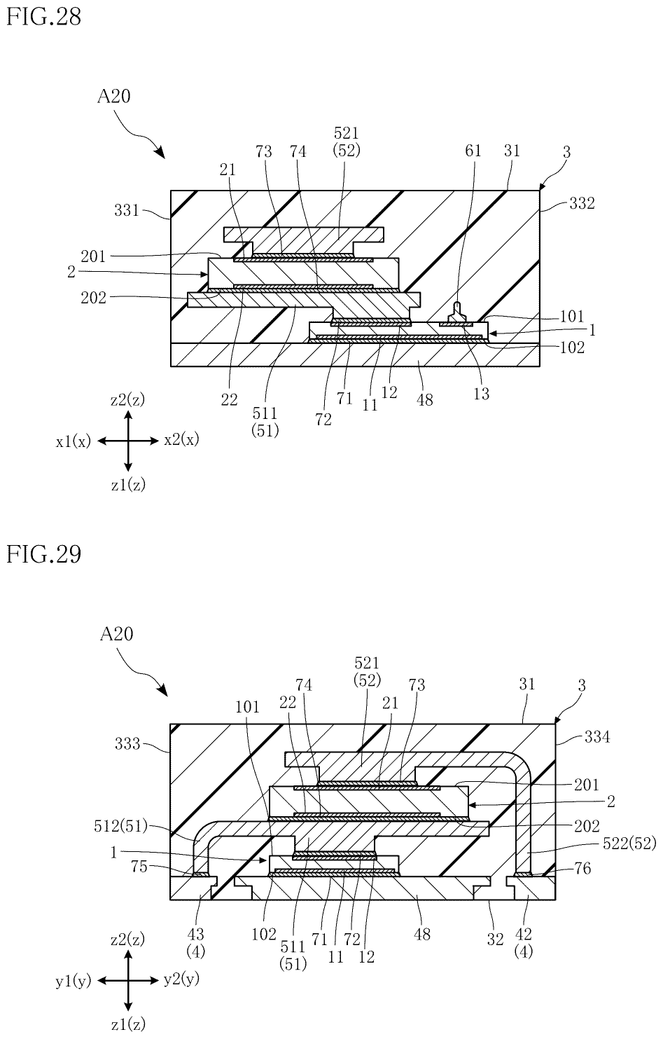

In the semiconductor device A20, the first terminal 41 is connected to the die pad 48 and integrally formed with the die pad 48. The electrode 11 (the drain) of the switching element 1 is bonded to the die pad 48. As shown in FIGS. 28 and 29, the die pad 48 and the electrode 11 are bonded with the bonding material 71. Thus, the first terminal 41 electrically conducts to the electrode 11 (the drain).

In the semiconductor device A20, the conductive plate 52 (the extension portion 522) is bonded to the second terminal 42. As shown in FIG. 29, the conductive plate 52 (the extension portion 522) and the second terminal 42 are bonded with the bonding material 76. The electrode 21 (the anode) of the semiconductor element 2 is bonded to the conductive plate 52 (the bond portion 521). As shown in FIGS. 28 and 29, the conductive plate 52 (the bond portion 521) and the electrode 21 are bonded with the bonding material 73. Thus, the second terminal 42 electrically conducts to the electrode 21 (the anode).

In the semiconductor device A20, the conductive plate 51 (the extension portion 512) is bonded to the third terminal 43. As shown in FIG. 29, the conductive plate 51 (the extension portion 512) and the third terminal 43 are bonded with the bonding material 75. The electrode 12 (the source) of the switching element 1 and the electrode 22 (the cathode) of the semiconductor element 2 are bonded to the conductive plate 51 (the bond portion 511). As shown in FIGS. 28 and 29, the conductive plate 51 (the bond portion 511) and the electrode 12 are bonded with the bonding material 72, and the conductive plate 51 (the bond portion 511) and the electrode 22 are bonded with the bonding material 74. Thus, the third terminal 43 electrically conducts to the electrode 12 (the source) and the electrode 22 (the cathode).

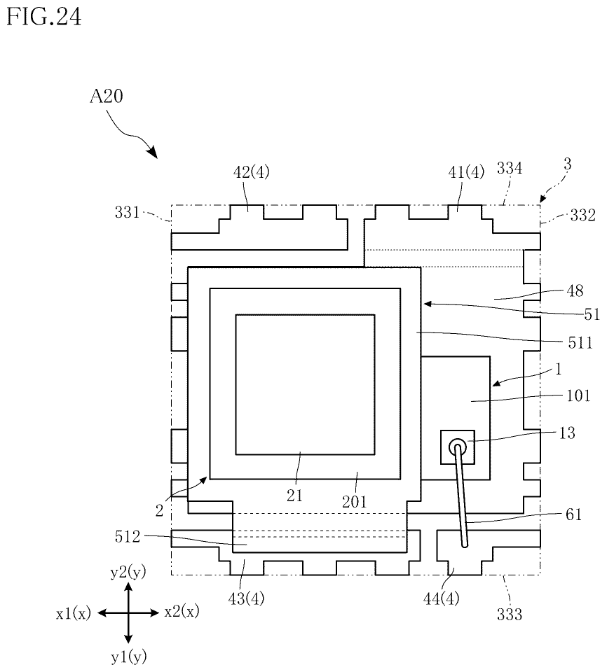

To the fourth terminal 44 is bonded the connecting member 61, which is bonded to the electrode 13 (the gate) of the switching element 1. Thus, the fourth terminal 44 electrically conducts to the electrode 13 (the gate). As shown in FIGS. 23 and 24, the switching element 1 is slightly displaced in the second direction x with respect to the two conductive plates 51 and 52 and the semiconductor element 2. Thus, the electrode 13 of the switching element 1 does not overlap with either of the two conductive plates 51 and 52 or the semiconductor element 2 as viewed in the thickness direction z, which makes it possible to bond the connecting member 61 to the electrode 13.

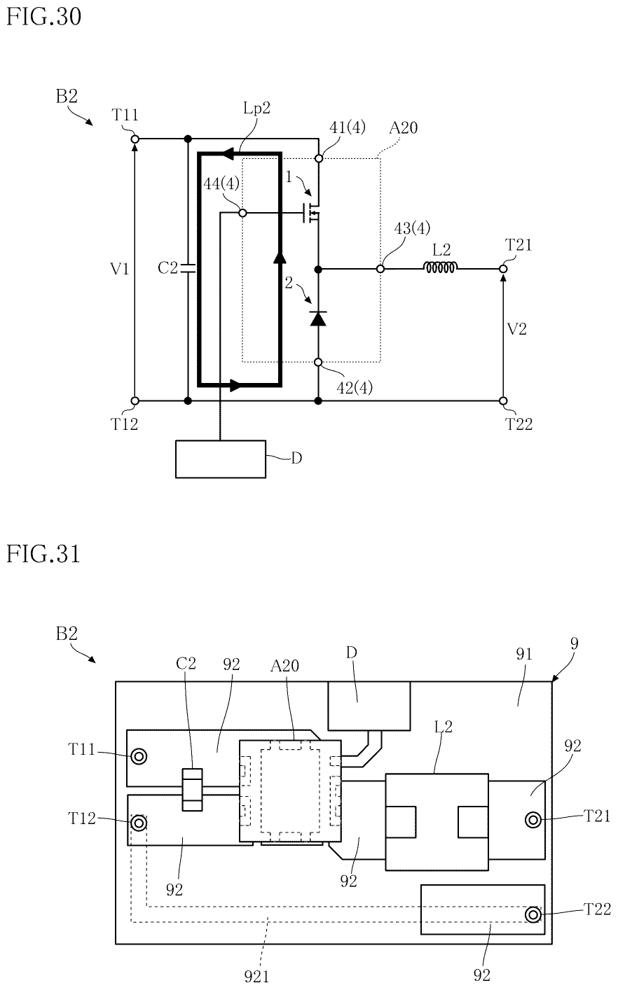

FIGS. 30 to 32 show an electronic device B2 that includes the semiconductor device A20. As shown in these figures, the electronic device B2 includes a mounting substrate 9, a capacitor C2, an inductor L2 and a drive circuit D, in addition to the semiconductor device A20.

As shown in FIG. 30, in the electronic device B2, the source (the electrode 12) of the switching element 1 and the cathode (the electrode 22) of the semiconductor element 2 are electrically connected to each other in the semiconductor device A20. The connection point of these electrically conducts to the third terminal 43. The inductor L2 is connected between the third terminal 43 and the output terminal T21. One of the electrodes of the capacitor C2 is electrically connected to the first terminal 41 of the semiconductor device A20, and the other electrode of the capacitor C2 is electrically connected to the second terminal 42 of the semiconductor device A20. That is, the capacitor C2 is connected to the drain (the electrode 11) of the switching element 1 and the anode (the electrode 21) of the semiconductor element 2. The capacitor C2 is connected to a pair of input terminals T11 and T12. The capacitor C2 functions as an input capacitor disposed on the input side of the semiconductor device A20. When the electronic device B2 (the switching element 1 and the semiconductor element 2) is energized, the potential of the first terminal 41 is higher than that of the second terminal 42, and the switching element 1 is connected to the higher potential side than the semiconductor element 2. In the example shown in FIG. 30, the electronic device B2 forms a step-down circuit (a step-down chopper circuit). The electronic device B2 reduces the voltage V1 applied to the pair of input terminals T11 and T12 to voltage V2 by the switching operation of the switching element 1. Then, the reduced voltage V2 is outputted from the pair of output terminals T21 and T22. The input terminal T12 and the output terminal T22 may be, for example, grounded.

The effects and advantages of the semiconductor device A20 and the electronic device B2 are as follows.

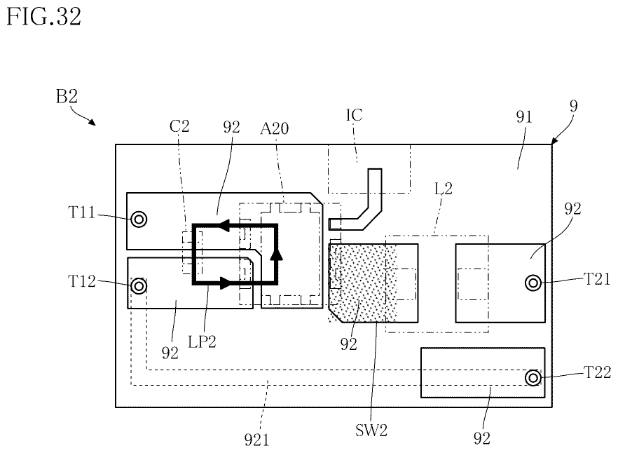

In the semiconductor device A20, the electrode 12 of the switching element 1 and the electrode 22 of the semiconductor element 2 are electrically connected to each other inside the sealing resin 3. In the semiconductor device A20, the electrode 12 is the source, and the electrode 22 is the cathode. With such a configuration, the conduction distance between the electrode 12 and the electrode 22 can be made shorter than when the switching element 1 and the semiconductor element 2 are provided by separate discrete components. With such a shortened conduction distance, when the electrode 12 and the electrode 22 are connected to the inductor L2 to form a step-down circuit by using the semiconductor device A20, the wiring area of the switching node (see SW2 in FIG. 32) can be reduced. Reducing the wiring area of the switching node is effective in reducing noise. Therefore, the semiconductor device A20 can reduce noise.

In the semiconductor device A20, the first terminal 41 and the second terminal 42 are adjacent to each other. The first terminal 41 electrically conducts to the electrode 11 of the switching element 1, and the second terminal 42 electrically conducts to the electrode 21 of the semiconductor element 2. In the semiconductor device A20, the electrode 11 is the drain, and the electrode 21 is the anode. With such a configuration, the separation distance between the first terminal 41 and the second terminal 42 can be made shorter than when the first terminal 41 and the second terminal 42 are disposed on opposite side surfaces of the sealing resin 3 (e.g., the resin side surface 333 and the resin side surface 334). With such a shortened separation distance, when the electrode 11 and the electrode 21 are connected to the capacitor C2 to form a step-down circuit by using the semiconductor device A20, the distance of the current loop Lp2 (see FIGS. 30 and 32) through the capacitor C2 can be shortened. Shortening the distance of the current loop Lp2 is effective in reducing noise. Therefore, the semiconductor device A20 can reduce noise.

The semiconductor device A20 has a configuration in common with the semiconductor devices A10 and A11, thereby achieving the same effect as the semiconductor devices A10 and A11.

### Variation of the Second Embodiment:

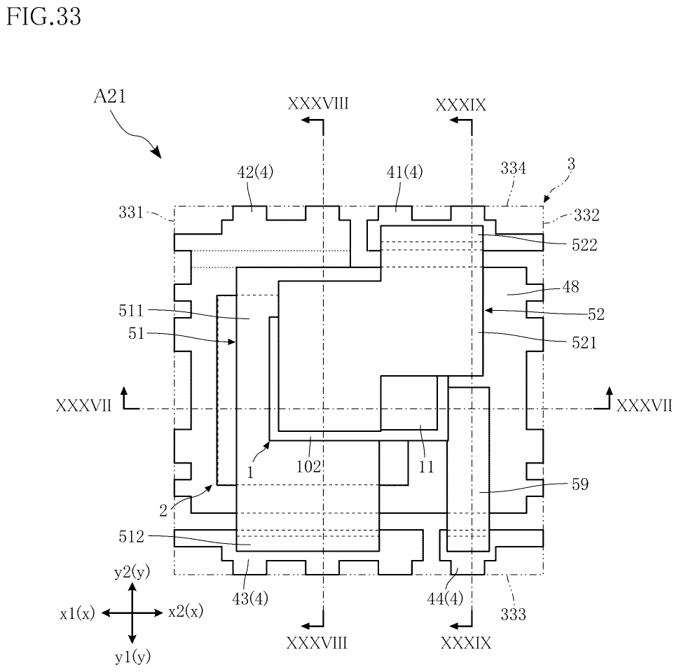

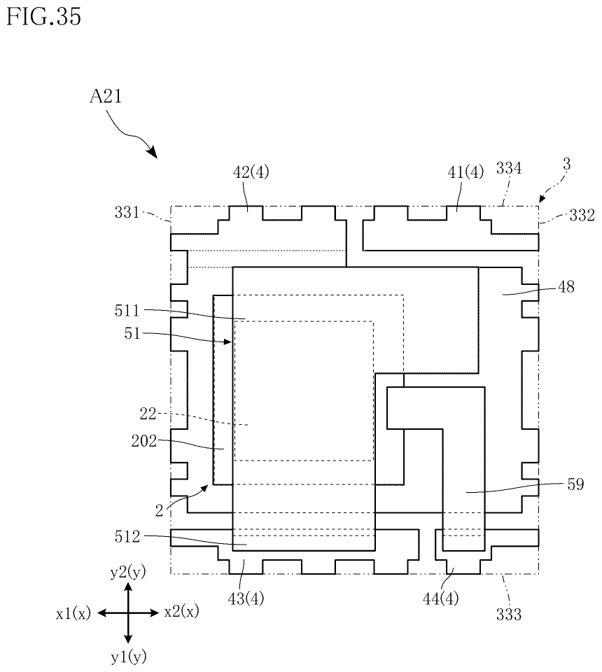

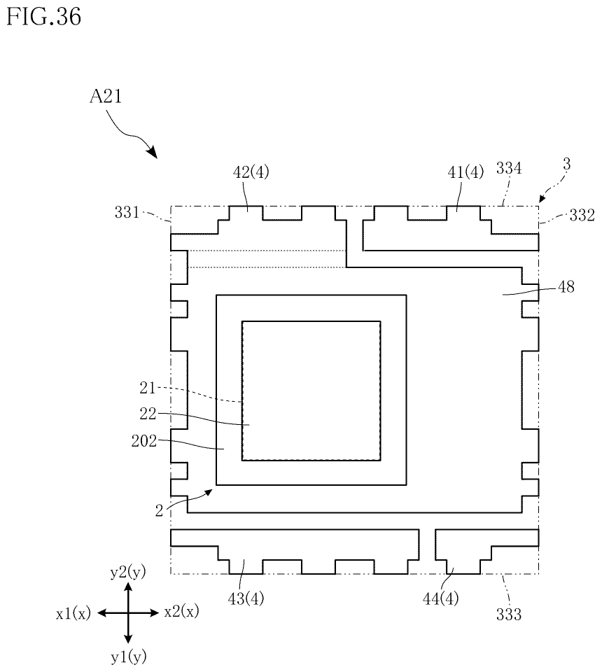

FIGS. 33 to 39 show a semiconductor device A21 according to a variation of the second embodiment. The semiconductor device A21 differs from the semiconductor device A20 in the following points. First, the switching element 1 is disposed on the z2 side in the thickness direction z of the conductive plate 51 (the bond portion 511), and the semiconductor element 2 is disposed on the z1 side in the thickness direction z of the conductive plate 51 (the bond portion 511). Second, the switching element 1 is disposed with the element obverse surface 101 facing the z1 side in the thickness direction z, and the semiconductor element 2 is disposed with the element obverse surface 201 facing the z1 side in the thickness direction z. As with the semiconductor device A20, the semiconductor device A21 is incorporated in the electronic device B2 as a part of a step-down circuit (see FIGS. 30 to 32). The bottom view of the semiconductor device A21 and the bottom view of the semiconductor device A10 are identical to each other in appearance.

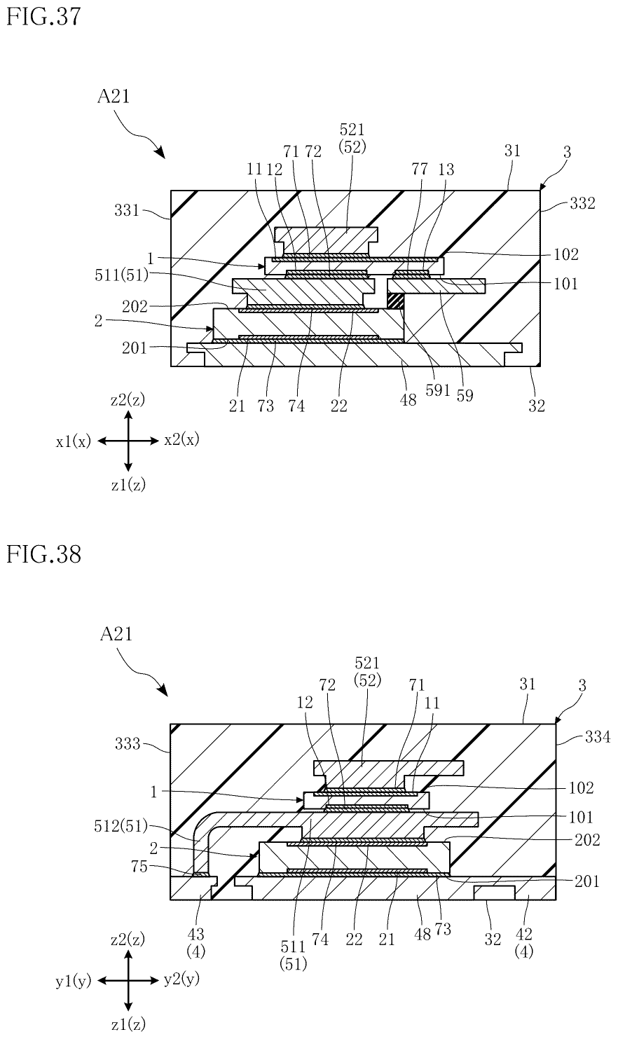

In the semiconductor device A21, as shown in FIGS. 37 and 38, the electrode 11 (the drain) of the switching element 1 is bonded to the conductive plate 52 (the bond portion 521) with the bonding material 71. The electrode 12 of the switching element 1 is bonded to the conductive plate 51 (the bond portion 511) with the bonding material 72. The electrode 21 of the semiconductor element 2 is bonded to the die pad 48 with the bonding material 73. The electrode 22 of the semiconductor element 2 is bonded to the conductive plate 51 (the bond portion 511) with the bonding material 74.

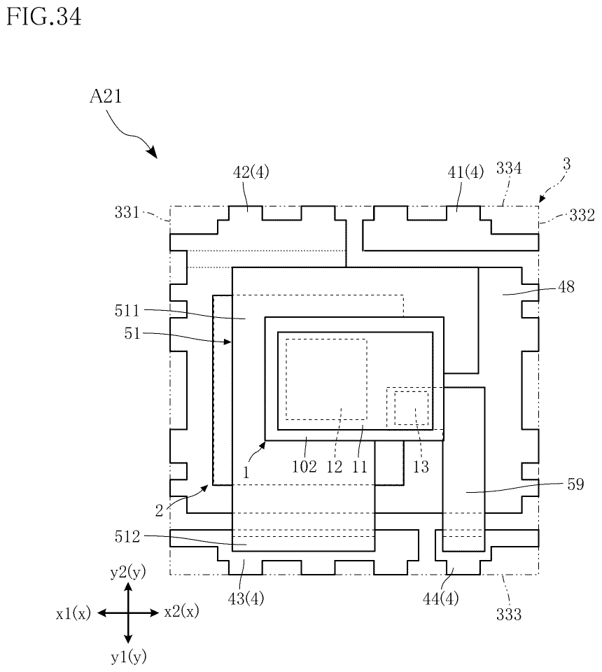

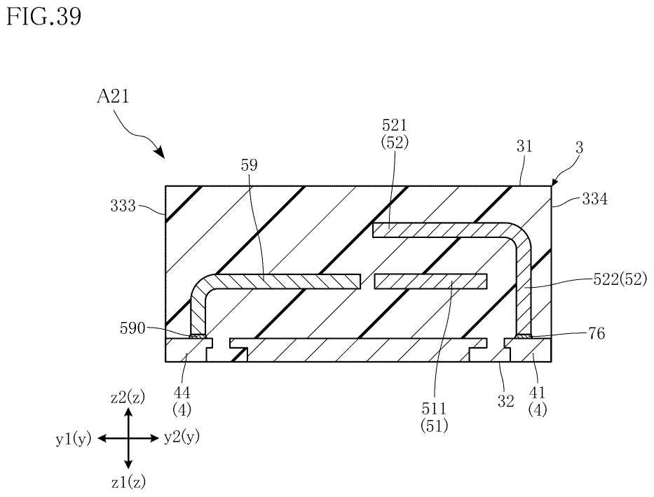

As shown in FIGS. 34, 35, 37, and 39, the semiconductor device A21 further includes a conductive plate 59. The conductive plate 59 may be made of, for example, a metal material. The metal material includes copper. The conductive plate 59 is not limited to one made of a metal material, and may be made of any material that conducts electricity. The conductive plate 59 is bonded to the electrode 13 (the gate) of the switching element 1 and the fourth terminal 44 to electrically conduct these. As shown in FIG. 37, the electrode 13 is bonded to the conductive plate 59 with the bonding material 77. As shown in FIG. 39, the conductive plate 59 is bonded to the fourth terminal 44 with the bonding material 590. The bonding material 590 may be, for example, solder, sintered metal, or metal paste. In the example shown in FIG. 37, the semiconductor device A21 includes an insulating block 591 to support the conductive plate 59 while providing insulation from the semiconductor element 2.

In the semiconductor device A21, the electrode 12 (the source) of the switching element 1 and the electrode 22 (the cathode) of the semiconductor element 2 are electrically connected to each other inside the sealing resin 3, as with in the semiconductor device A20. Therefore, the semiconductor device A21 can reduce noise, as with the semiconductor device A20. Further, in the semiconductor device A21, the first terminal 41, which electrically conducts to the electrode 11 (the drain) of the switching element 1, and the second terminal 42, which electrically conducts to the electrode 21 (the anode) of the semiconductor element 2, are adjacent to each other, as with in the semiconductor device A20. Therefore, the semiconductor device A21 can reduce noise, as with the semiconductor device A20. Additionally, the semiconductor device A21 has a configuration in common with the semiconductor devices A10, A11, and A20, thereby achieving the same effect as the semiconductor devices A10, A11, and A21.

In the semiconductor device A21, the semiconductor element 2 is mounted on the die pad 48. The electrode 21 of the semiconductor element 2 is bonded to the die pad 48. In the present embodiment, the electrode 21 is the anode. The semiconductor device A21 is used in a step-down circuit as with the semiconductor device A20, and the electrode 21 of the semiconductor element 2 may be grounded. Therefore, the electrode 21 of the semiconductor element 2 is connected to the ground of the mounting substrate 9 via the die pad 48. This is effective in improving the heat dissipation of the semiconductor device A21. That is, the semiconductor device A21 can improve heat dissipation more than the semiconductor device A20.

### Third Embodiment

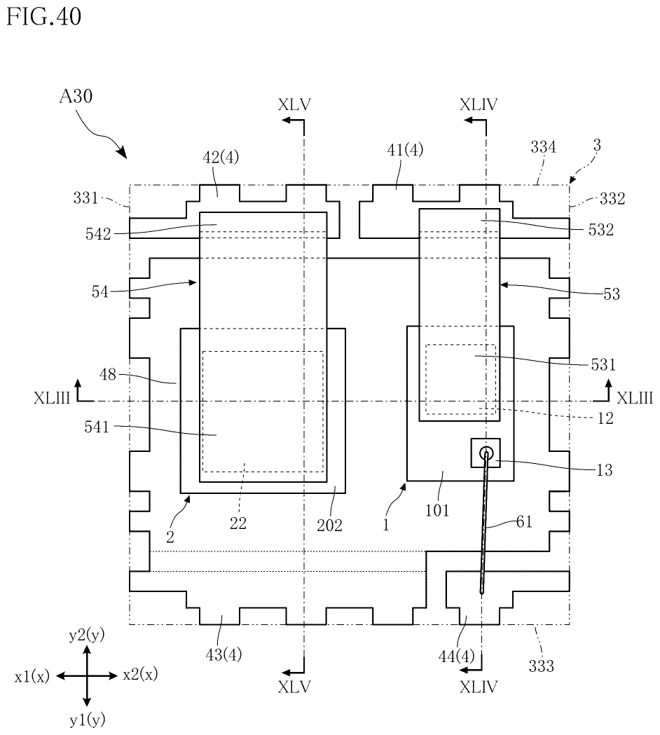

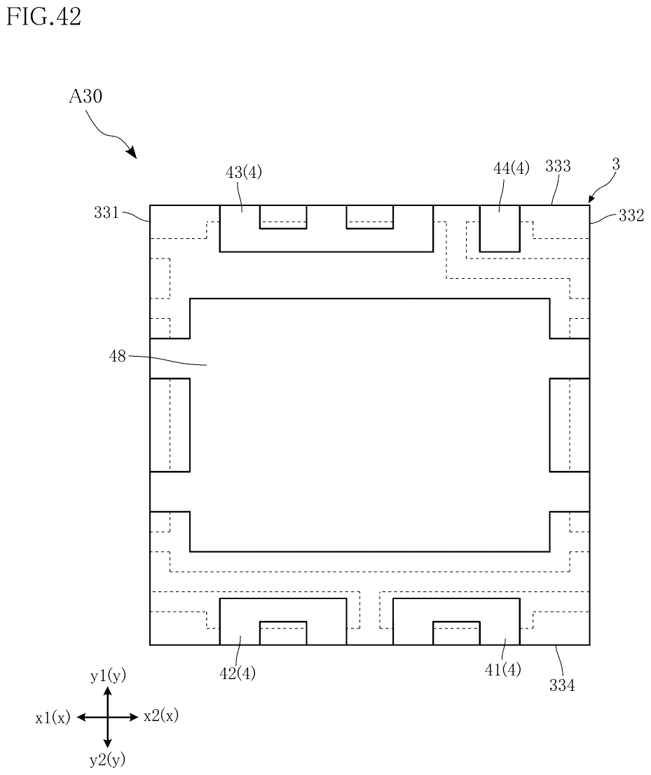

FIGS. 40 to 45 show a semiconductor device A30 according to a third embodiment. The semiconductor device A30 differs from the semiconductor device A10 in the following point. That is, the switching element 1 and the semiconductor element 2 do not overlap with each other as viewed in the thickness direction z. As with the semiconductor device A10, the semiconductor device A30 is incorporated in the electronic device B1 as a part of a step-up circuit (see FIGS. 13 to 15).

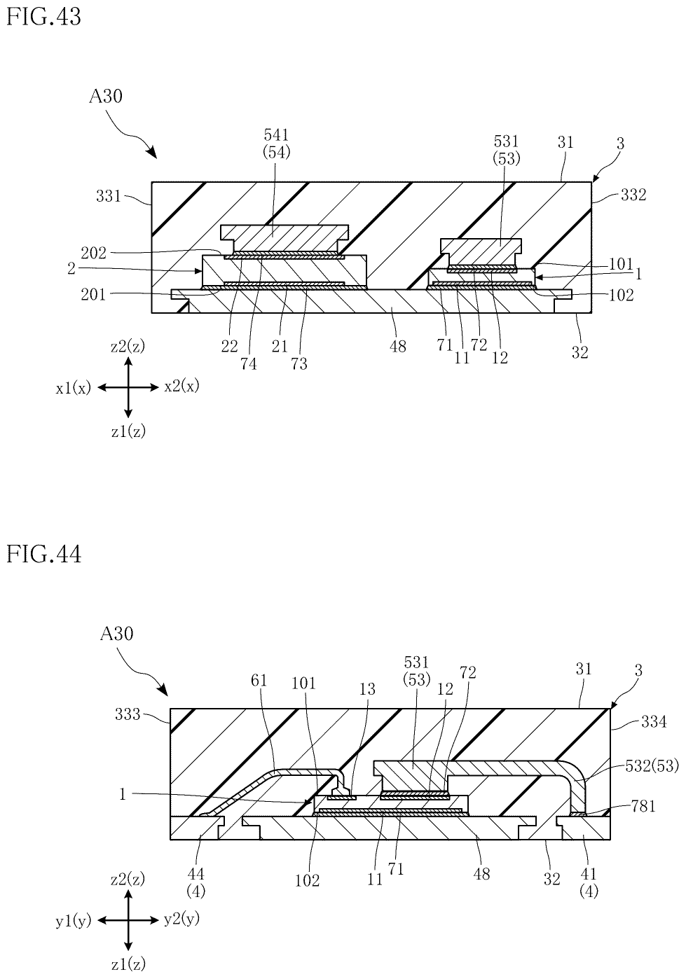

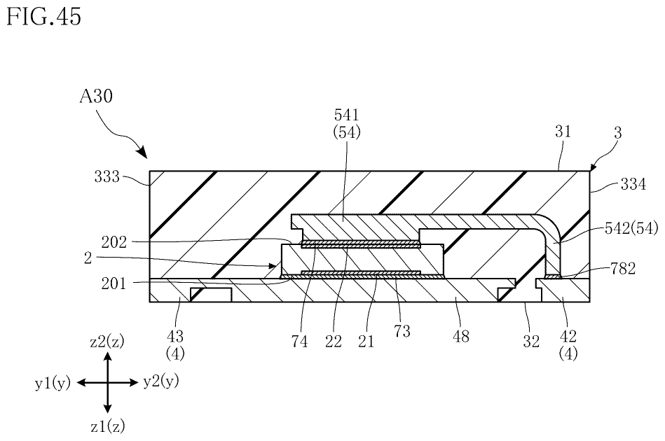

In the semiconductor device A30, the switching element 1 and the semiconductor element 2 are mounted on the die pad 48 as shown in FIGS. 40, 41, and 43. In the present embodiment, the switching element 1 is disposed with the element reverse surface 102 facing the z1 side in the thickness direction z. Thus, as shown in FIGS. 43 and 44, the element reverse surface 102 faces the die pad 48, and the electrode 11 (the drain) is bonded to the die pad 48 with the bonding material 71. Thus, the die pad 48 electrically conducts to the electrode 11. The semiconductor element 2 is disposed with the element obverse surface 201 facing the z1 side in the thickness direction z. Thus, as shown in FIGS. 43 and 45, the element obverse surface 201 faces the die pad 48, and the electrode 21 (the anode) is bonded to the die pad 48 with the bonding material 73. Thus, the die pad 48 electrically conducts to the electrode 21.

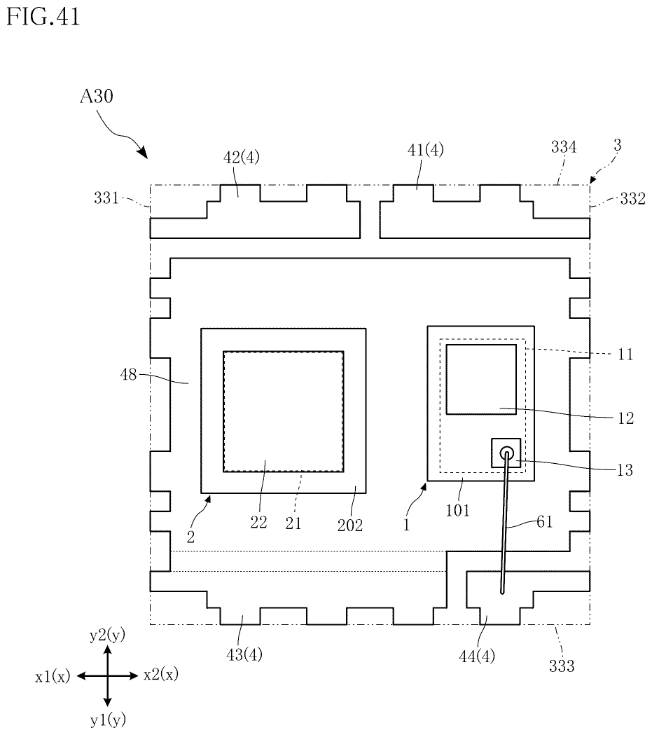

In the semiconductor device A30, the third terminal 43 is connected to the die pad 48 and integrally formed with the die pad 48 as shown in FIGS. 40 and 41. Because the die pad 48 electrically conducts to the electrode 11 and the electrode 21 as mentioned before, the third terminal 43 electrically conducts to the electrode 11 (the drain) and the electrode 21 (the anode) via the die pad 48.

The semiconductor device A30 includes two conductive plates 53 and 54 instead of the two conductive plates 51 and 52. The two conductive plates 53 and 54 are made of a metal material. The metal material may include, for example, copper. The two conductive plates 53 and 52 are not limited to ones made of a metal material, and may be made of any material that conducts electricity.

As shown in FIGS. 40 and 44, the conductive plate 53 includes a bond portion 531 and an extension portion 532. The bond portion 531 and the extension portion 532 are integrally formed. The bond portion 531 is disposed on the switching element 1. As shown in FIGS. 43 and 44, the bond portion 531 partially projects downward (to the z1 side) in the thickness direction z. In the present embodiment, the projecting portion is bonded to the electrode 12 (the source) of the switching element 1. Unlike this example, the bond portion 531 may be partially bent downward (to the z1 side) in the thickness direction z, and the bent portion may be bonded to the electrode 12. The extension portion 532 is bonded to the first terminal 41. The extension portion 532 extends from the bond portion 531 downward (to the z1 side) in the thickness direction z. The conductive plate 53 electrically connects the first terminal 41 and the electrode 12.

As shown in FIGS. 40 and 45, the conductive plate 54 includes a bond portion 541 and an extension portion 542. The bond portion 541 and the extension portion 542 are integrally formed. The bond portion 541 is disposed on the semiconductor element 2. As shown in FIGS. 43 and 45, the bond portion 541 partially projects downward (to the z1 side) in the thickness direction z. In the present embodiment, the projecting portion is bonded to the electrode 22 (the cathode) of the semiconductor element 2. Unlike this example, the bond portion 541 may be partially bent downward (to the z1 side) in the thickness direction z, and the bent portion may be bonded to the electrode 22. The extension portion 542 is bonded to the second terminal 42. The extension portion 542 extends from the bond portion 541 downward (to the z1 side) in the thickness direction z. The conductive plate 54 electrically connects the second terminal 42 and the electrode 22.

As shown in FIG. 43, in the semiconductor device A30, the bonding material 71 is interposed between the electrode 11 and the die pad 48 to conductively bond these. The bonding material 72 is interposed between the electrode 12 and the conductive plate 53 (the bond portion 531) to conductively bond these. The bonding material 73 is interposed between the electrode 21 and the die pad 48 to conductively bond these. The bonding material 74 is interposed between the electrode 22 and the conductive plate 54 (the bond portion 541) to conductively bond these.

The semiconductor device A30 further includes two bonding materials 781 and 782. The two bonding materials 781 and 782 may be, for example, solder. The two bonding materials 781 and 782 may be sintered metal or metal paste rather than solder. The bonding material 781 bonds the conductive plate 53 (the extension portion 532). As shown in FIG. 44, the bonding material 781 is interposed between the conductive plate 53 (the extension portion 532) and the first terminal 41 to conductively bond these. The bonding material 782 bonds the conductive plate 54 (the extension portion 542). As shown in FIG. 45, the bonding material 782 is interposed between the conductive plate 54 (the extension portion 542) and the second terminal 42 to conductively bond these. In FIGS. 40 and 41, illustration of the bonding materials 71 to 74, 781 and 782 is omitted.

In the semiconductor device A30, the electrode 11 (the drain) of the switching element 1 and the electrode 21 (the anode) of the semiconductor element 2 are electrically connected to each other inside the sealing resin 3, as with in the semiconductor device A10. Therefore, the semiconductor device A30 can reduce noise, as with the semiconductor device A10. Further, in the semiconductor device A30, the first terminal 41, which electrically conducts to the electrode 12 (the source) of the switching element 1, and the second terminal 42, which electrically conducts to the electrode 22 (the cathode) of the semiconductor element 2, are adjacent to each other, as with in the semiconductor device A10. Therefore, the semiconductor device A30 can reduce noise, as with the semiconductor device A10. Additionally, the semiconductor device A30 has a configuration in common with the semiconductor devices A10, A11, A20 and A21, thereby achieving the same effect as the semiconductor devices A10, A11, A20 and A21.

In the semiconductor device A30, the switching element 1 and the semiconductor element 2 do not overlap with each other as viewed in the thickness direction z. In the present configuration, the switching element 1 and the semiconductor element 2 are disposed along a plane orthogonal to the thickness direction z. Therefore, the semiconductor device A30 can reduce the dimension in the thickness direction z more than semiconductor device A10.

### Variation of the Third Embodiment:

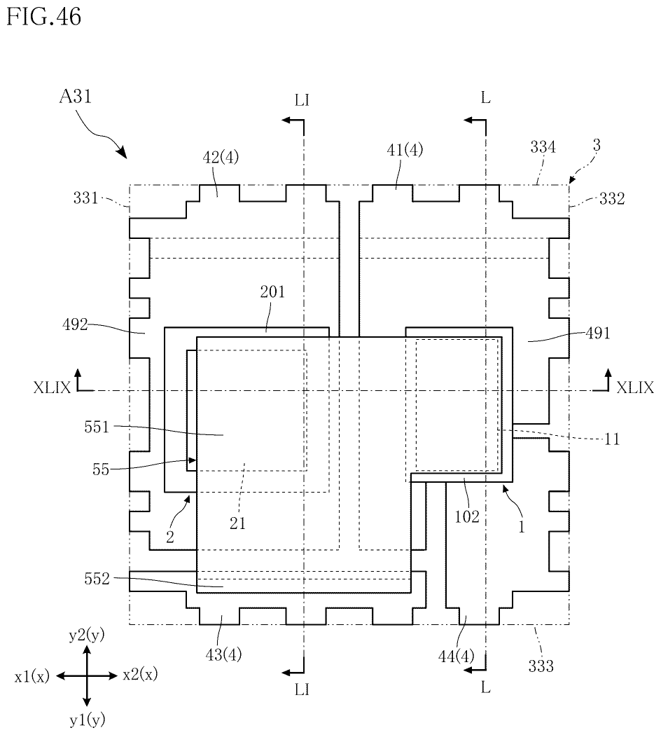

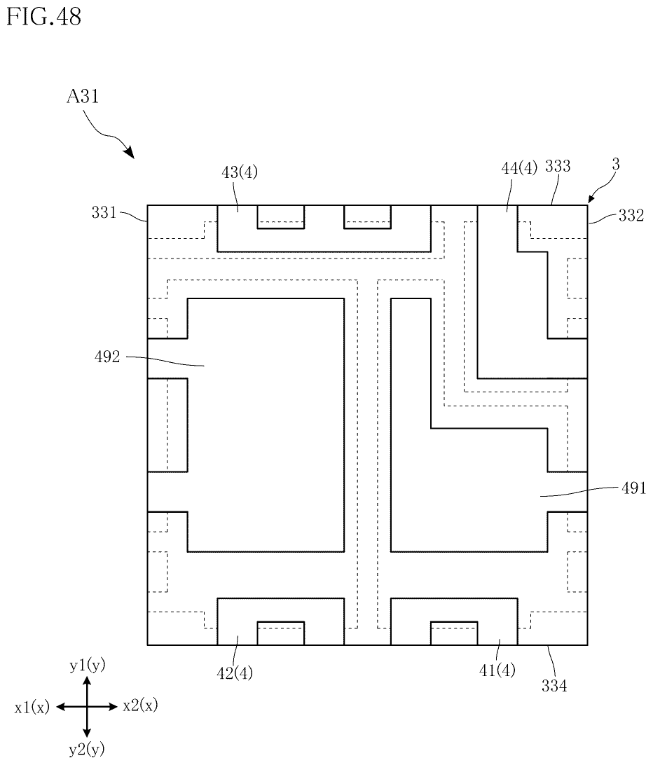

FIGS. 46 to 51 show a semiconductor device A31 according to a variation of the third embodiment. The semiconductor device A31 differs from the semiconductor device A30 in the following points. First, the switching element 1 is disposed with the element obverse surface 101 facing the z1 side in the thickness direction z. Second, the semiconductor element 2 is disposed with the element reverse surface 202 facing the z1 side in the thickness direction z. Thirdly, the semiconductor device A31 includes two die pads 491 and 492 instead of the die pad 48. Fourthly, the semiconductor device A31 does not include the two conductive plates 53 and 54, but includes a conductive plate 55. As with the semiconductor device A30, the semiconductor device A31 is incorporated in the electronic device B1 as a part of a step-up circuit.

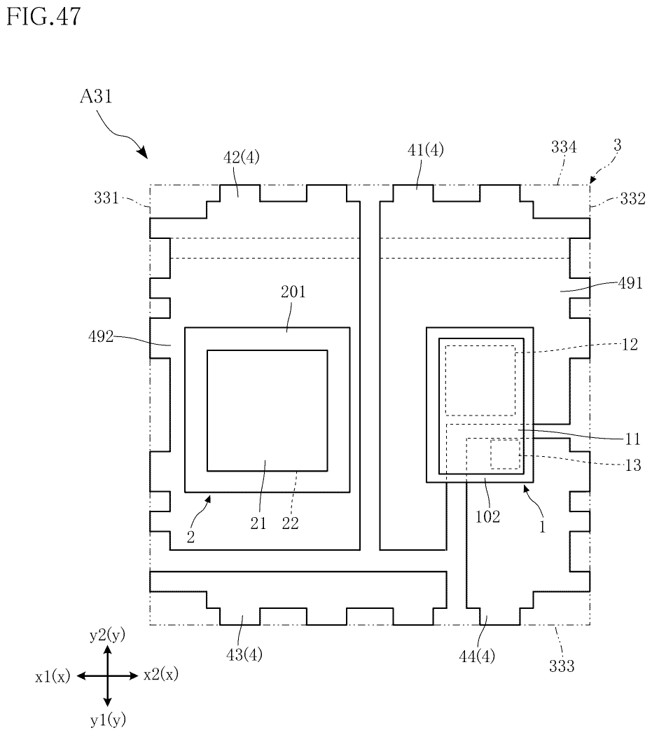

The two die pads 491 and 492 are spaced apart from each other. In the example shown in FIG. 47, the two die pads 491 and 492 are disposed along the second direction x. The third terminal 43 is not connected to either of the two die pads 491 and 492.

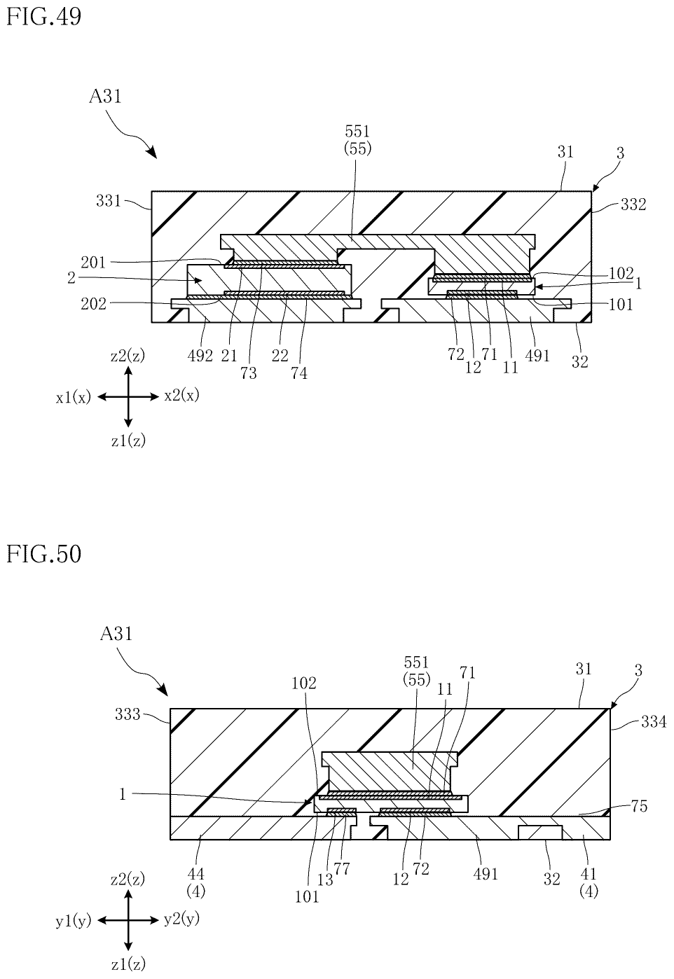

As shown in FIGS. 47 and 49, on the die pad 491, the switching element 1 is mounted and the electrode 12 (the source) is bonded. The first terminal 41 is connected to the die pad 491. The first terminal 41 and the die pad 491 are integrally formed. Thus, the first terminal 41 electrically conducts to the electrode 12 (the source) via the die pad 491.

As shown in FIGS. 47 and 49, on the die pad 492, the semiconductor element 2 is mounted and the electrode 22 (the cathode) is bonded. The second terminal 42 is connected to the die pad 492. The second terminal 42 and the die pad 492 are integrally formed. Thus, the second terminal 42 electrically conducts to the electrode 22 (the cathode) via the die pad 492.

The conductive plate 55 is made of a metal material. The metal material may include, for example, copper. The conductive plate 55 is not limited to one made of a metal material, and may be made of any material that conducts electricity.

As shown in FIGS. 46 and 49 to 51, the conductive plate 55 includes a bond portion 551 and a extension portion 552. The bond portion 551 and the extension portion 552 are integrally formed. The bond portion 551 bridges over the switching element 1 and the semiconductor element 2 as viewed in the thickness direction z. The bond portion 551 is bonded to the electrode 11 (the drain) of the switching element 1 and bonded to the electrode 21 (the anode) of the semiconductor element 2. As shown in FIG. 49, the bond portion 551 partially projects downward (to the z1 side) in the thickness direction z, and the projecting portion is bonded to the electrode 11 and the electrode 21. Unlike this example, the bond portion 551 may be partially bent downward (to the z1 side) in the thickness direction z, and the bent portion may be bonded to the electrode 11 and the electrode 21. The extension portion 552 is bonded to the third terminal 43. The extension portion 552 extends from the bond portion 551 downward (to the z1 side) in the thickness direction z. The conductive plate 55 electrically connects the third terminal 43 to the electrode 11 and the electrode 21.

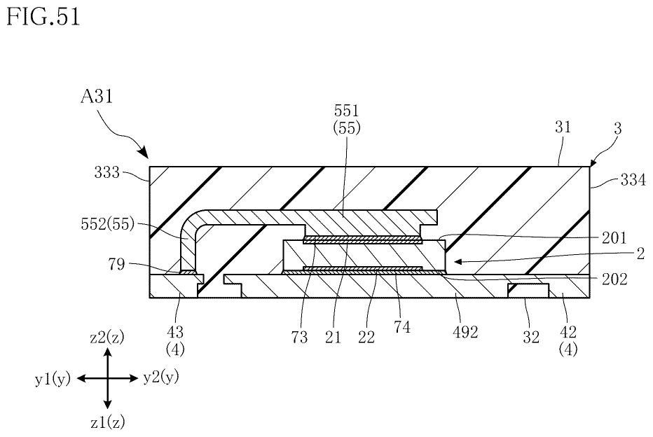

The semiconductor device A31 further includes a bonding material 79. The bonding material 79 may be, for example, solder. The bonding material 79 may be sintered metal or metal paste rather than solder. The bonding material 79 bonds the conductive plate 55 (the extension portion 552). As shown in FIG. 51, the bonding material 79 is interposed between the conductive plate 55 (the extension portion 552) and the third terminal 43 to conductively bond these. In FIGS. 46 and 47, illustration of the bonding materials 71 to 74, 77 and 79 is omitted.

In the semiconductor device A31, the electrode 11 (the drain) of the switching element 1 and the electrode 21 (the anode) of the semiconductor element 2 are electrically connected to each other inside the sealing resin 3, as with in the semiconductor device A30. Therefore, the semiconductor device A31 can reduce noise, as with the semiconductor device A30. Further, in the semiconductor device A31, the first terminal 41, which electrically conducts to the electrode 12 (the source) of the switching element 1, and the second terminal 42, which electrically conducts to the electrode 22 (the cathode) of the semiconductor element 2, are adjacent to each other, as with in the semiconductor device A30. Therefore, the semiconductor device A31 can further reduce noise, as with the semiconductor device A30. Additionally, the semiconductor device A31 has a configuration in common with the semiconductor devices A10, A11, A20, A21 and A30, thereby achieving the same effect as the semiconductor devices A10, A11, A20, A21 and A30.

### Fourth Embodiment

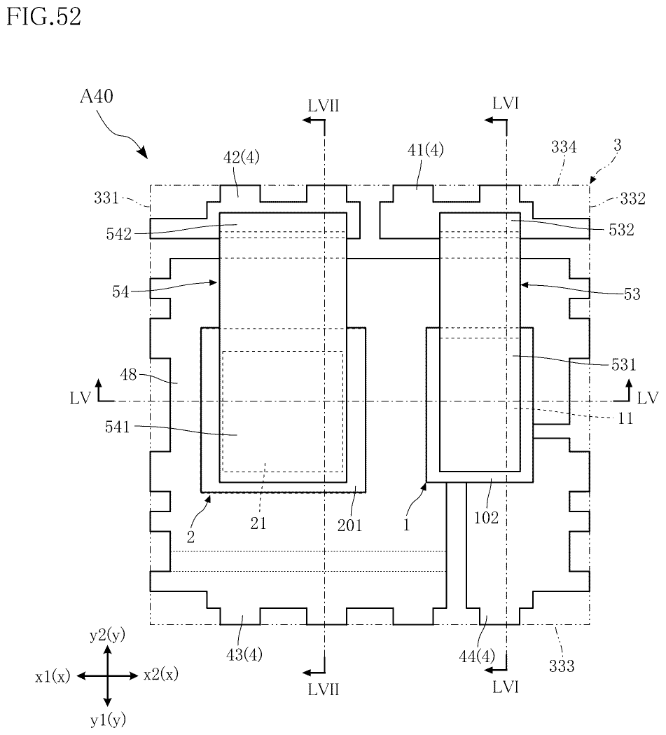

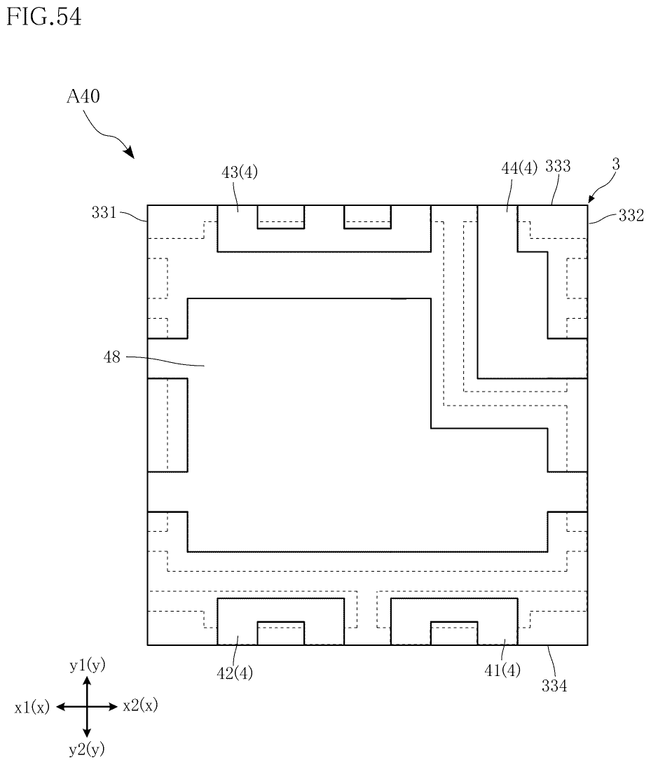

FIGS. 52 to 57 show a semiconductor device A40 according to a fourth embodiment. The semiconductor device A40 differs from the semiconductor device A30 in the following points. First, the switching element 1 is disposed with the element obverse surface 101 facing the z1 side in the thickness direction z. Second, the semiconductor element 2 is disposed with the element reverse surface 202 facing the z1 side in the thickness direction z. As with the semiconductor device A20, the semiconductor device A40 is incorporated in the electronic device B2 as a part of a step-down circuit (see FIGS. 30 to 32).

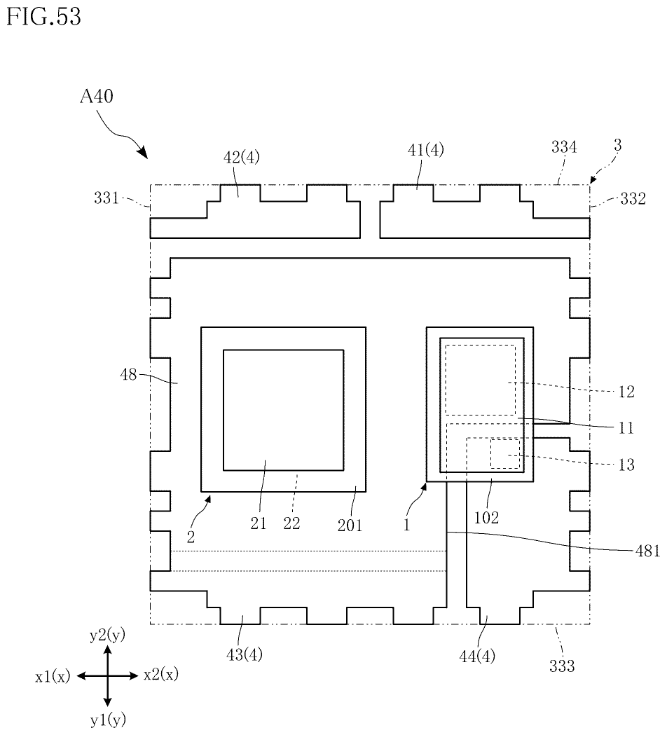

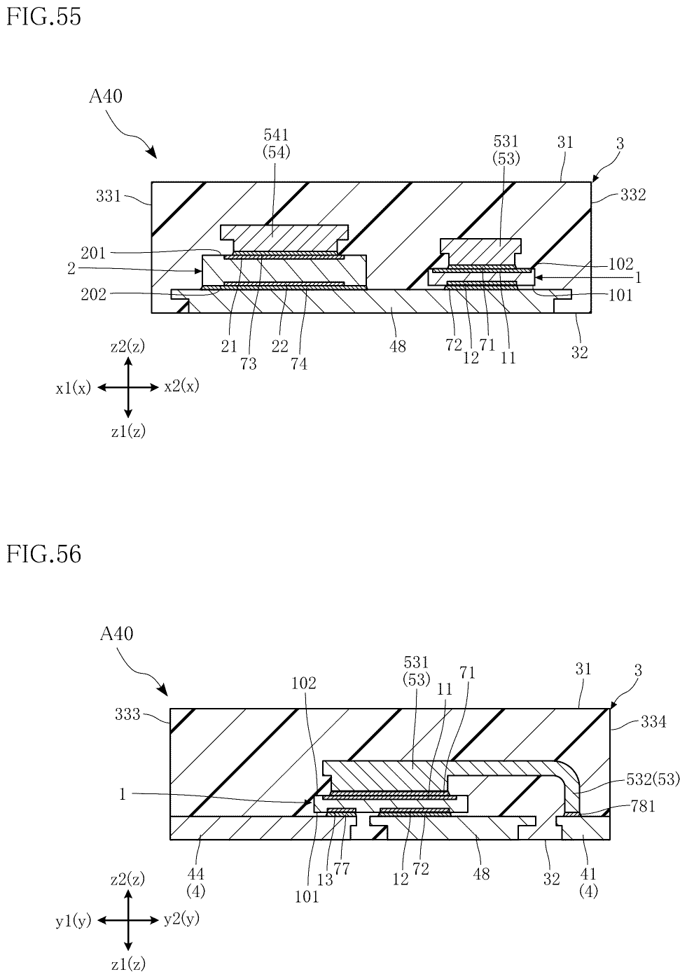

In the semiconductor device A40, the electrode 11 (the drain) of the switching element 1 is bonded to the conductive plate 53 (the bond portion 531) with the bonding material 71 as shown in FIGS. 55 and 56. Because the conductive plate 53 (the extension portion 532) is bonded to the first terminal 41 with the bonding material 781, the first terminal 41 electrically conducts to the electrode 11. The electrode 12 (the source) of the switching element 1 is bonded to the die pad 48 with the bonding material 72. Because the die pad 48 is connected to the third terminal 43, the third terminal 43 electrically conducts to the electrode 12. As shown in FIG. 56, the electrode 13 (the gate) of the switching element 1 is bonded to the fourth terminal 44 with the bonding material 77. Thus, the fourth terminal 44 electrically conducts to the electrode 13. In FIGS. 52 and 53, illustration of the bonding materials 71 to 74, 781 and 782 is omitted.

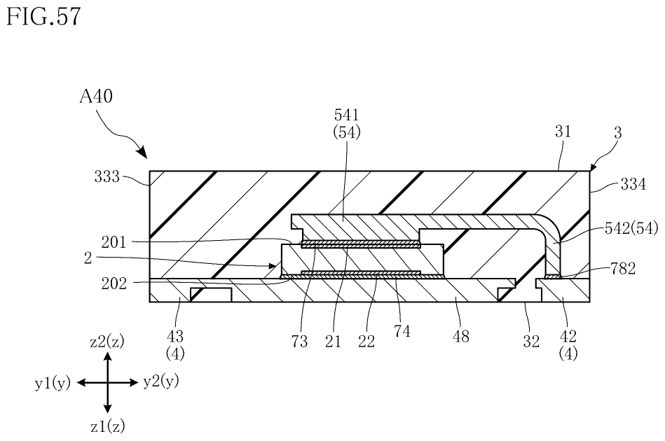

In the semiconductor device A40, the electrode 21 (the anode) of the semiconductor element 2 is bonded to the conductive plate 54 (the bond portion 541) with the bonding material 73 as shown in FIGS. 55 and 57. Because the conductive plate 54 (the extension portion 542) is bonded to the second terminal 42 with the bonding material 782, the second terminal 42 electrically conducts to the electrode 21. The electrode 22 (the cathode) of the semiconductor element 2 is bonded to the die pad 48 with the bonding material 74. Because the die pad 48 is connected to the third terminal 43, the third terminal 43 electrically conducts to the electrode 22.

In the semiconductor device A40, the electrode 12 (the source) of the switching element 1 and the electrode 22 (the cathode) of the semiconductor element 2 are electrically connected to each other inside the sealing resin 3, as with in the semiconductor device A20. Therefore, the semiconductor device A40 can reduce noise, as with the semiconductor device A20. Further, in the semiconductor device A40, the first terminal 41, which electrically conducts to the electrode 11 (the drain) of the switching element 1, and the second terminal 42, which electrically conducts to the electrode 21 (the anode) of the semiconductor element 2, are adjacent to each other, as with in the semiconductor device A20. Therefore, the semiconductor device A40 can further reduce noise, as with the semiconductor device A20. Additionally, the semiconductor device A40 has a configuration in common with the semiconductor devices A10, A11, A20, A21, A30 and A31, thereby achieving the same effect as the semiconductor devices A10, A11, A20, A21, A30 and A31.

### Variation of the Fourth Embodiment:

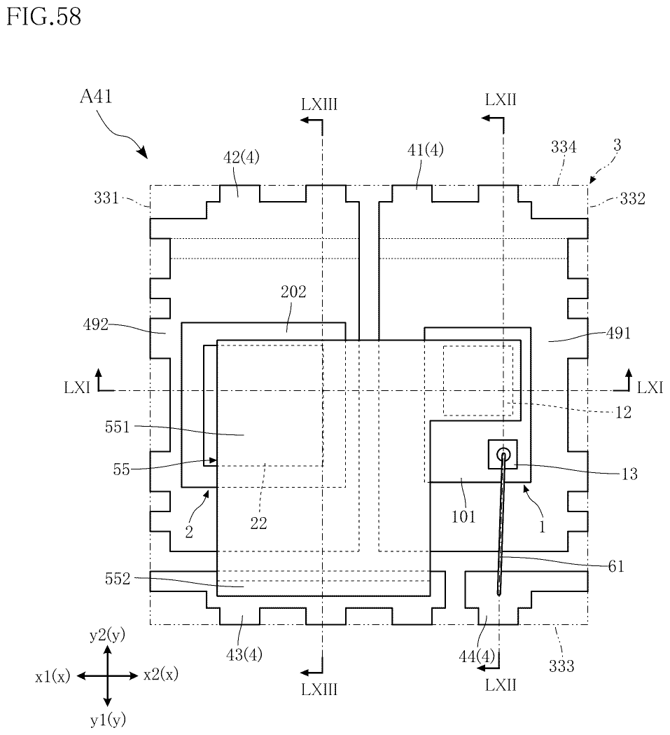

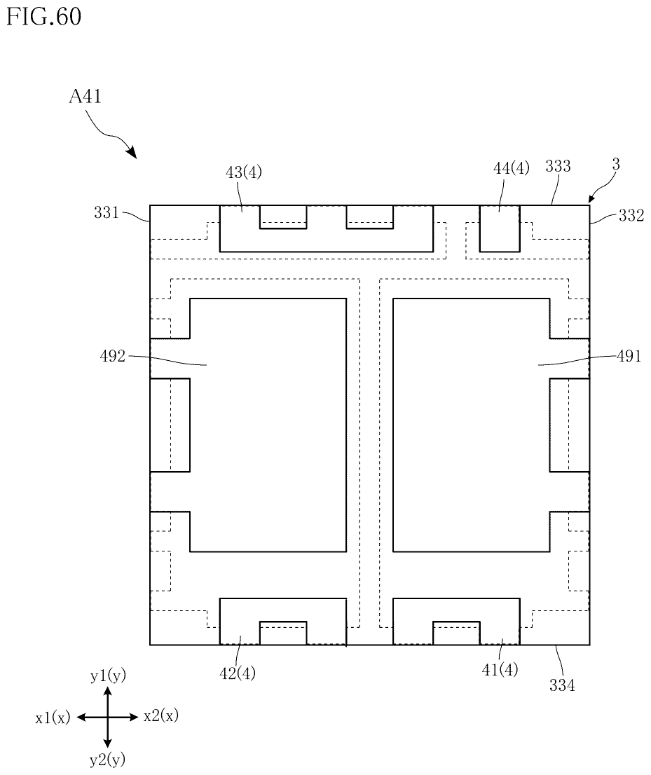

FIGS. 58 to 63 show a semiconductor device A41 according to a variation of the fourth embodiment. The semiconductor device A41 differs from the semiconductor device A40 in the following points. First, the switching element 1 is disposed with the element obverse surface 101 facing the z2 side in the thickness direction z. Second, the semiconductor element 2 is disposed with the element reverse surface 202 facing the z2 side in the thickness direction z. Thirdly, the semiconductor device A41 includes two die pads 491 and 492 instead of the die pad 48. Fourthly, the semiconductor device A41 does not include the two conductive plates 53 and 54, but includes a conductive plate 55. As with the semiconductor device A40, the semiconductor device A41 is incorporated in the electronic device B2 as a part of a step-down circuit.

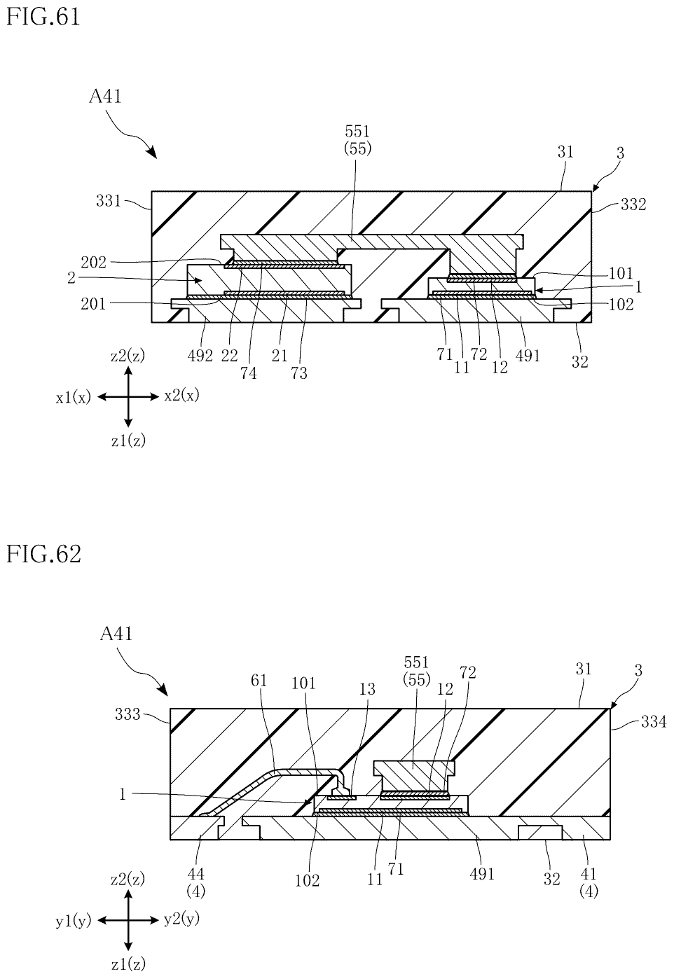

In the semiconductor device A41, the electrode 11 (the drain) of the switching element 1 is bonded to the die pad 491 with the bonding material 71 as shown in FIGS. 61 and 62. Because the die pad 491 is connected to the first terminal 41, the first terminal 41 electrically conducts to the electrode 11. The electrode 12 (the source) of the switching element 1 is bonded to conductive plate 55 (the bond portion 551) with the bonding material 72. Because the conductive plate 55 (the extension portion 552) is bonded to the third terminal 43 with the bonding material 79, the third terminal 43 electrically conducts to the electrode 12. As shown in FIG. 62, the electrode 13 (the gate) of the switching element 1 is bonded to the fourth terminal 44 via the connecting member 61.

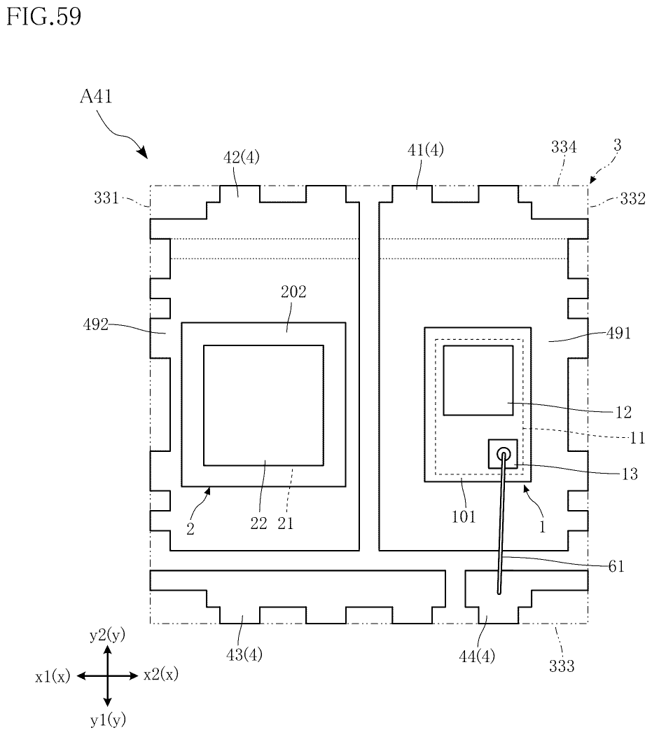

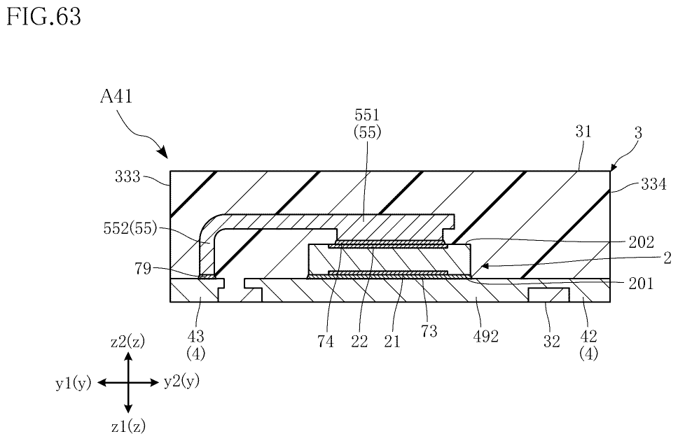

In the semiconductor device A41, the electrode 21 (the anode) of the semiconductor element 2 is bonded to the die pad 492 with the bonding material 73 as shown in FIGS. 61 and 63. Because the die pad 492 is connected to the second terminal 42, the second terminal 42 electrically conducts to the electrode 21. The electrode 22 (the cathode) of the semiconductor element 2 is bonded to the conductive plate 55 (the bond portion 551) with the bonding material 74. Because the conductive plate 55 (the extension portion 552) is bonded to the third terminal 43 with the bonding material 79, the third terminal 43 electrically conducts to the electrode 22. In FIGS. 58 and 59, illustration of the bonding materials 71 to 74 and 79 is omitted.

In the semiconductor device A41, the electrode 12 (the source) of the switching element 1 and the electrode 22 (the cathode) of the semiconductor element 2 are electrically connected to each other inside the sealing resin 3, as with in the semiconductor device A40. Therefore, the semiconductor device A41 can reduce noise, as with the semiconductor device A40. Further, in the semiconductor device A41, the first terminal 41, which electrically conducts to the electrode 11 (the drain) of the switching element 1, and the second terminal 42, which electrically conducts to the electrode 21 (the anode) of the semiconductor element 2, are adjacent to each other, as with in the semiconductor device A40. Therefore, the semiconductor device A41 can further reduce noise, as with the semiconductor device A40. Additionally, the semiconductor device A41 has a configuration in common with the semiconductor devices A10, A11, A20, A21, A30, A31 and A40, thereby achieving the same effect as the semiconductor devices A10, A11, A20, A21, A30, A31 and A40.

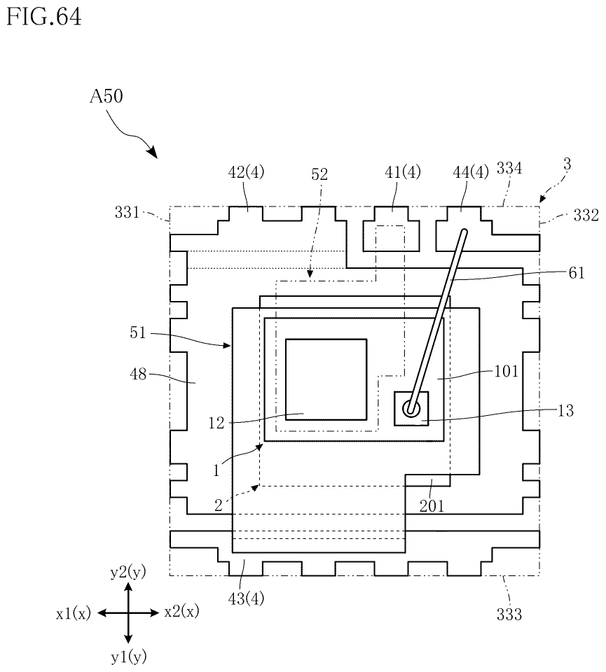

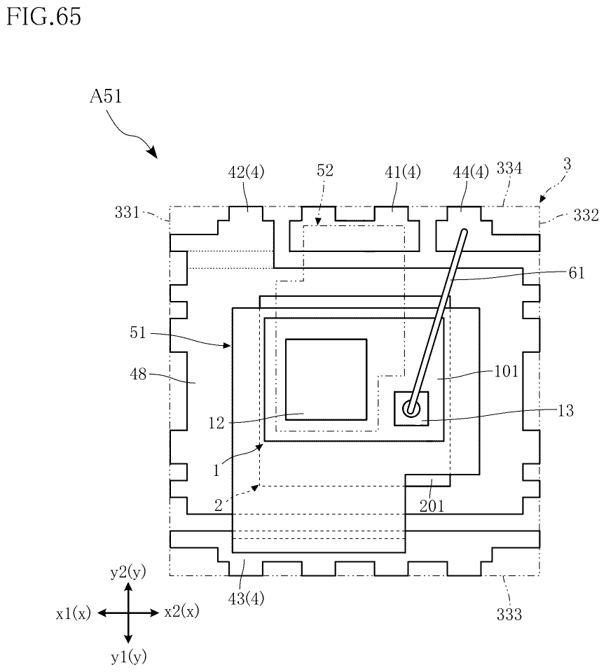

In examples different from the first through the fourth embodiments (including the variations thereof) described above, the fourth terminal 44 may be exposed on the resin side surface 334 where the first terminal 41 and the second terminal 42 are exposed. That is, the fourth terminal 44 may be disposed on the same side as the first terminal 41 and the second terminal 42 with respect to the die pad 48 in the first direction y. FIGS. 64 and 65 illustrate semiconductor devices A50 and A51, respectively, according to such a variation. In FIGS. 64 and 65, the sealing resin 3 and the conductive plate 52 are indicated by imaginary lines.

Each of the semiconductor devices A50 and A51 has a configuration in which the fourth terminal 44 is disposed on the x2 side in the second direction x of the first terminal 41 in the semiconductor device A10. Though the fourth terminal 44 is disposed on the x2 side in the second direction x of the first terminal 41 in the illustrated example, the fourth terminal 44 may be disposed on the x1 side in the second direction x of the second terminal 42. In the semiconductor device A50, the area of the second terminal 42 as viewed in the thickness direction z is larger than the area of the first terminal 41 as viewed in the thickness direction z. In the semiconductor device A51, in contrast, the area of the first terminal 41 as viewed in the thickness direction z is larger than the area of the second terminal 42 as viewed in the thickness direction z.

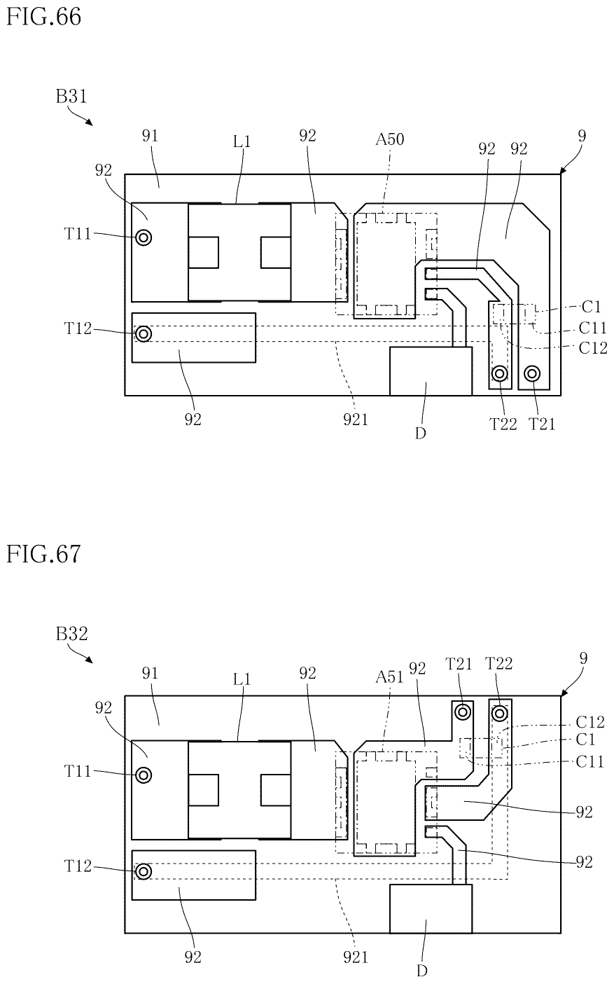

FIG. 66 shows an electronic device B31 that includes the semiconductor device A50. In the electronic device B31, the conduction distance (the first distance) from the location of the semiconductor device A50 to the electrode C11 on the higher potential side of the capacitor C1 differs from the conduction distance (the second distance) from the location of the semiconductor device A50 to the electrode C12 on the lower potential side of the capacitor C1. In the example shown in FIG. 66, the first distance is greater than the second distance. In such an example, the configuration in which the second terminal 42 is larger than the first terminal 41 is favorable for shortening the first distance. The first distance and the second distance form a part of the current loop Lp1 as mentioned before, so that shortening the first distance is effective in shortening the distance of the current loop Lp1. That is, in the electronic device B31 in which the first distance is larger than the second distance, the semiconductor device A50 is advantageous for shortening the current loop Lp1 (i.e., reducing the noise). FIG. 67 shows an electronic device B32 that includes the semiconductor device A51. In the example shown in FIG. 67, the above second distance is greater than the above first distance. In such an example, the configuration in which the first terminal 41 is larger than the second terminal 42 is favorable for shortening the second distance. The first distance and the second distance form a part of the current loop Lp1 as mentioned before, so that shortening the second distance is effective in shortening the distance of the current loop Lp1. That is, in the electronic device B32 in which the second distance is larger than the first distance, the semiconductor device A51 is advantageous for shortening the current loop Lp1 (i.e., reducing the noise).

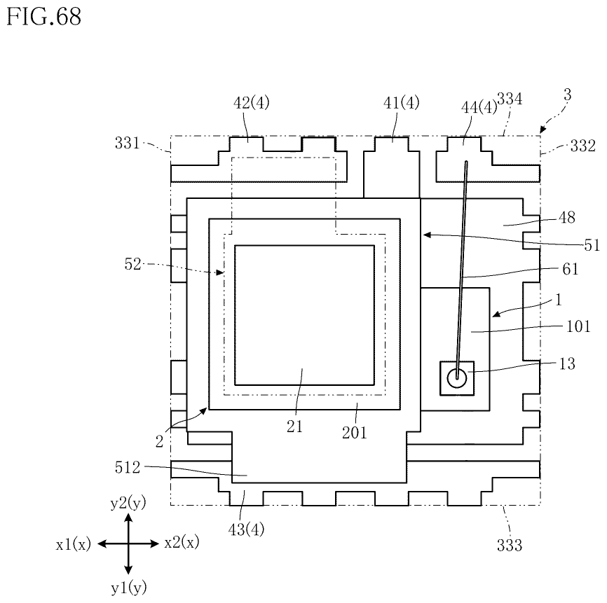

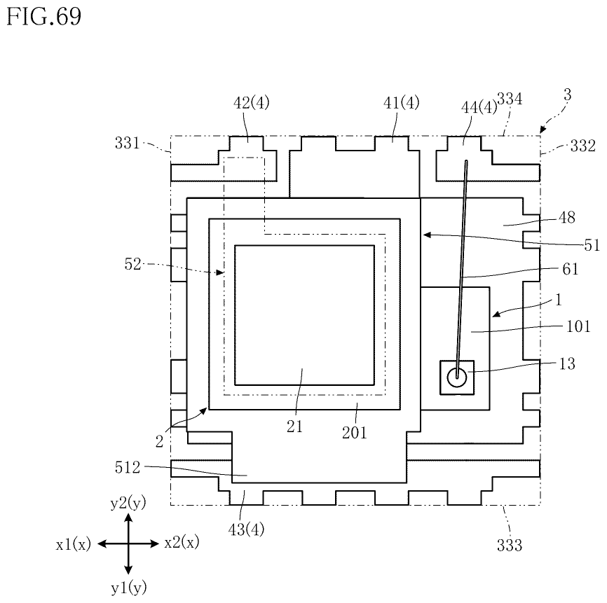

Although the semiconductor devices A50 and A51 are shown as examples in which the position of the fourth terminal 44 in the semiconductor device A10 is changed, the position of the fourth terminal 44 may be changed also in other semiconductor devices A11, A20, A21, A30, A31, A40 and A41. For example, FIGS. 68 and 69 show a configuration in which the fourth terminal 44 is exposed from the resin side surface 334 in the semiconductor device A20. In the example shown in FIG. 68, the area of the second terminal 42 as viewed in the thickness direction z is larger than the area of the first terminal 41 as viewed in the thickness direction z. In FIG. 69, in contrast, the area of the first terminal 41 as viewed in the thickness direction z is larger than the area of the second terminal 42 as viewed in the thickness direction z.

Although the examples in which the size relationship between the first terminal 41 and the second terminal 42 is advantageous for shortening the current loop Lp1 are shown as the semiconductor devices A50 and A51, unlike these examples, the size relationship between the first terminal 41 and the second terminal 42 may be set so as to shorten the distance from the input terminal T11 to the output terminal T21.

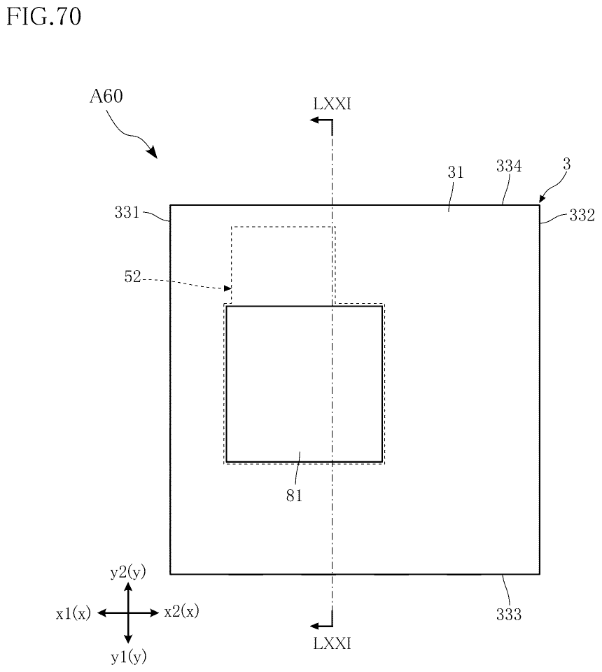

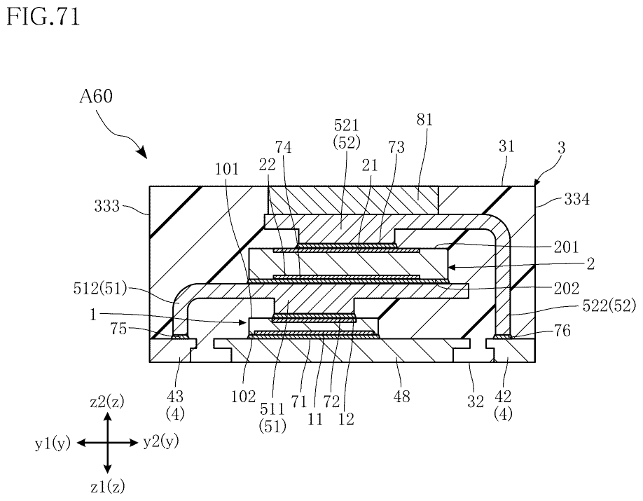

In the first through the fourth embodiments (including the variations thereof), a heat dissipation pad exposed from the resin obverse surface 31 may also be provided. FIGS. 70 and 71 show a semiconductor device A60 according to such a variation. The semiconductor device A60 has a configuration in which a heat dissipation pad 81 is provided in the semiconductor device A20.

The heat dissipation pad 81 is disposed on the z2 side in the thickness direction z of the bond portion 521 of the conductive plate 52. The heat dissipation pad 81 is in contact with the bond portion 521 of the conductive plate 52. An insulating layer may be interposed between the heat dissipation pad 81 and the bond portion 521. It is preferable that the insulating layer has good thermal conductivity. The heat dissipation pad 81 is exposed from the resin obverse surface 31. The upper surface (the surface facing the z2 side in the thickness direction z) of the heat dissipation pad 81 is flush with the resin obverse surface 31 in the example shown in FIG. 71, but may project to the z2 side in the thickness direction z relative to the resin obverse surface 31 or may be recessed to the z1 side in the thickness direction z.

Although the example in which the heat dissipation pad 81 is provided in the semiconductor device A20 is shown as the semiconductor device A60, the heat dissipation pad 81 may be provided in other semiconductor devices A10, A11, A21, A30, A31, A40 and A41. In the semiconductor devices A30 and A40, a single heat dissipation pad 81 may be provided to bridge over the two conductive plates 53 and 54, two heat dissipation pads 81 may be provided individually on the two conductive plates 53 and 54, or a heat dissipation pad 81 may be provided on only one of the two conductive plates 53 and 54. In the semiconductor devices A31 and A41, the heat dissipation pad 81 is disposed on the conductive plate 55.

Although the semiconductor element 2 is a diode (SBD) in the first through the fourth embodiments (including the variations thereof), the semiconductor element 2 may be a switching element similar to the switching element 1. That is, the semiconductor device of the present disclosure is not limited to one that forms a step-up circuit or a step-down circuit of the asynchronous rectification type, in which a switching element and a diode are connected in series, but may be one that forms a step-up circuit or a step-down circuit of the synchronous rectification type, in which two switching elements are connected in series. In such an example, the plurality of terminals 4 include terminals for inputting drive signals for the semiconductor element 2.

The semiconductor device and the electronic device according to the present disclosure is not limited to the above-described embodiments. Various modifications in design may be made freely in the specific structure of each part of the semiconductor device and the electronic device according to the present disclosure. The present disclosure includes embodiments described in the following clauses.
Clause 1.
   A semiconductor device comprising:
      a switching element including a first electrode, a second electrode, and a third electrode and configured to conduct a current between the first electrode and the second electrode in response to a drive signal inputted to the third electrode;
      a semiconductor element including a fourth electrode and a fifth electrode and configured to conduct a current between the fourth electrode and the fifth electrode;
      a sealing resin covering the switching element and the semiconductor element; and
      a plurality of terminals each of which is partially exposed from the sealing resin, wherein
      the first electrode and the fourth electrode are electrically connected inside the sealing resin,
      the plurality of terminals include a first terminal, a second terminal, and a third terminal,
      the first terminal electrically conducts to the second electrode,
      the second terminal electrically conducts to the fifth electrode,
      the third terminal electrically conducts to each of the first electrode and the fourth electrode, and
      the first terminal and the second terminal are adjacent to each other.
Clause 2.
   The semiconductor device according to clause 1, wherein the switching element and the semiconductor element overlap with each other as viewed in a thickness direction of the sealing resin.
Clause 3.
   The semiconductor device according to clause 2, further comprising a first conductive plate to which each of the first electrode and the fourth electrode is bonded,
      wherein the first conductive plate is sandwiched between the switching element and the semiconductor element in the thickness direction and bonded to the third terminal.
Clause 4.
   The semiconductor device according to clause 3, further comprising a die pad on which the switching element is mounted with the second electrode being bonded to the die pad, wherein
      the switching element is sandwiched between the die pad and the first conductive plate in the thickness direction, and
      the first terminal is connected to the die pad.
Clause 5.
   The semiconductor device according to clause 4, further comprising a second conductive plate bonded to the fifth electrode, wherein
      the semiconductor element is sandwiched between the first conductive plate and the second conductive plate in the thickness direction, and
      the second conductive plate is bonded to the second terminal.
Clause 6.
   The semiconductor device according to clause 3, further comprising a die pad on which the semiconductor element is mounted with the fifth electrode being bonded to the die pad, wherein
      the semiconductor element is sandwiched between the die pad and the first conductive plate in the thickness direction, and
      the second terminal is connected to the die pad.
Clause 7.
   The semiconductor device according to clause 6, further comprising a second conductive plate bonded to the second electrode, wherein
      the switching element is sandwiched between the first conductive plate and the second conductive plate in the thickness direction, and
      the second conductive plate is bonded to the first terminal.
Clause 8.
   The semiconductor device according to clause 5 or 7, further comprising a heat dissipation pad disposed on a side opposite to the switching element and the semiconductor element with respect to the second conductive plate, wherein
      the sealing resin includes a resin obverse surface and a resin reverse surface spaced apart from each other in the thickness direction,
      each of the plurality of terminals is exposed from the resin reverse surface, and
      the heat dissipation pad is exposed from the resin obverse surface.
Clause 9.
   The semiconductor device according to clause 1, wherein the switching element and the semiconductor element do not overlap with each other as viewed in a thickness direction of the sealing resin.
Clause 10.
   The semiconductor device according to clause 9, further comprising a die pad on which each of the switching element and the semiconductor element is mounted, wherein
      the first electrode and the fourth electrode are bonded to the die pad, and
      the third terminal is connected to the die pad.
Clause 11.
   The semiconductor device according to clause 10, further comprising:
      a first conductive plate bonded to the second electrode, and
      a second conductive plate bonded to the fourth electrode, wherein
      the first conductive plate is bonded to the first terminal, and
      the second conductive plate is bonded to the second terminal.
Clause 12.
   The semiconductor device according to clause 9, further comprising:
      a first die pad on which the switching element is mounted with the second electrode being bonded to the first die pad; and
      a second die pad on which the semiconductor element is mounted with the fifth electrode being bonded to the second die pad, wherein
      the first die pad and the second die pad are spaced apart from each other,
      the first terminal is connected to the first die pad, and
      the second terminal is connected to the second die pad.
Clause 13.
   The semiconductor device according to clause 12, further comprising a conductive plate to which each of the first electrode and the fourth electrode is bonded,
      wherein the conductive plate is bonded to the third terminal.
Clause 14.
   The semiconductor device according to any one of clauses 2 to 13, wherein the sealing resin includes a first resin side surface and a second resin side surface facing away from each other in a first direction orthogonal to the thickness direction,
      each of the first terminal and the second terminal is exposed from the first resin side surface, and
      the third terminal is exposed from the second resin side surface.
Clause 15.
   The semiconductor device according to clause 14, wherein the plurality of terminals include a fourth terminal electrically conducting to the third electrode.
Clause 16.
   The semiconductor device according to clause 15, wherein the fourth terminal is exposed from the second resin side surface.
Clause 17.
   The semiconductor device according to clause 15, wherein the fourth terminal is exposed from the first resin side surface.
Clause 18.
   The semiconductor device according to any one of clauses 1 to 17, wherein when the switching element and the semiconductor element are energized, a potential at the first terminal is higher than a potential at the second terminal, and
      the switching element is connected to a higher potential side than the semiconductor element.
Clause 19.
   The semiconductor device according to any one of clauses 1 to 17, wherein when the switching element and the semiconductor element are energized, a potential at the second terminal is higher than a potential at the first terminal, and
      the semiconductor element is connected to a higher potential side than the switching element.
Clause 20.
   The semiconductor device according to any one of clauses 1 to 19, wherein the switching element is a transistor, and
      the semiconductor element is a diode.
Clause 21.
   An electronic device comprising:
      the semiconductor device as set forth in any one of clauses 1 to 20;
      a capacitor; and
      a mounting substrate on which the semiconductor device and the capacitor are mounted, wherein
      the capacitor includes an electrode electrically connected to the first terminal, and
      the capacitor includes another electrode electrically connected to the second terminal.
Clause 22.
   The electronic device according to clause 21, further comprising an inductor mounted on the mounting substrate,
      wherein the inductor is electrically connected to the third terminal.

### REFERENCE NUMERALS

A10, A11, A20, A21, A30, A31, A40, A41: Semiconductor device
A50, A51, A60: Semiconductor device B1, B2, B31, B32: Electronic device
C1, C2: Capacitor C11: Electrode C12: Electrode D: Drive circuit
L1, L2: Inductor Lp1, Lp2: Current loop T11, T12: Input terminal
T21, T22: Output terminal 1: Switching element 101: Element obverse surface
102: Element reverse surface 11, 12, 13: Electrode 2: Semiconductor element
201: Element obverse surface 202: Element reverse surface 21, 22: Electrode
3: Sealing resin 31: Resin obverse surface 32: Resin reverse surface
331, 332, 333, 334: Resin side surface 4: Terminal 41: First terminal
42: Second terminal 43: Third terminal 44: Fourth terminal
48, 491, 492: Die pad 481: Cutout 51, 52, 53, 54, 55, 59: Conductive plate
511, 521, 531, 541, 551: Bond portion 512, 522, 532, 542, 552: Extension portion
521a: Cutout 590: Bonding material 591: Block 61: Connecting member
71 to 77, 781, 782, 79: Bonding material 81: Heat dissipation pad 9: Mounting substrate
91: Base 92: Wiring pattern 921: Reverse-surface wiring

1. A semiconductor device comprising:
a switching element including a first electrode, a second electrode, and a third electrode and configured to conduct a current between the first electrode and the second electrode in response to a drive signal inputted to the third electrode;
a semiconductor element including a fourth electrode and a fifth electrode and configured to conduct a current between the fourth electrode and the fifth electrode;
a sealing resin covering the switching element and the semiconductor element; and
a plurality of terminals each of which is partially exposed from the sealing resin, wherein
the first electrode and the fourth electrode are electrically connected inside the sealing resin,
the plurality of terminals include a first terminal, a second terminal, and a third terminal,
the first terminal electrically conducts to the second electrode,
the second terminal electrically conducts to the fifth electrode,
the third terminal electrically conducts to each of the first electrode and the fourth electrode, and
the first terminal and the second terminal are adjacent to each other.

2. The semiconductor device according to claim 1, wherein the switching element and the semiconductor element overlap with each other as viewed in a thickness direction of the sealing resin.

3. The semiconductor device according to claim 2, further comprising a first conductive plate to which each of the first electrode and the fourth electrode is bonded,
wherein the first conductive plate is sandwiched between the switching element and the semiconductor element in the thickness direction and bonded to the third terminal.

4. The semiconductor device according to claim 3, further comprising a die pad on which the switching element is mounted with the second electrode being bonded to the die pad, wherein
the switching element is sandwiched between the die pad and the first conductive plate in the thickness direction, and
the first terminal is connected to the die pad.

5. The semiconductor device according to claim 4, further comprising a second conductive plate bonded to the fifth electrode, wherein
the semiconductor element is sandwiched between the first conductive plate and the second conductive plate in the thickness direction, and
the second conductive plate is bonded to the second terminal.

6. The semiconductor device according to claim 3, further comprising a die pad on which the semiconductor element is mounted with the fifth electrode being bonded to the die pad, wherein
the semiconductor element is sandwiched between the die pad and the first conductive plate in the thickness direction, and
the second terminal is connected to the die pad.

7. The semiconductor device according to claim 6, further comprising a second conductive plate bonded to the second electrode, wherein
the switching element is sandwiched between the first conductive plate and the second conductive plate in the thickness direction, and
the second conductive plate is bonded to the first terminal.

8. The semiconductor device according to claim 5, further comprising a heat dissipation pad disposed on a side opposite to the switching element and the semiconductor element with respect to the second conductive plate, wherein
the sealing resin includes a resin obverse surface and a resin reverse surface spaced apart from each other in the thickness direction,
each of the plurality of terminals is exposed from the resin reverse surface, and
the heat dissipation pad is exposed from the resin obverse surface.

9. The semiconductor device according to claim 1, wherein the switching element and the semiconductor element do not overlap with each other as viewed in a thickness direction of the sealing resin.

10. The semiconductor device according to claim 9, further comprising a die pad on which each of the switching element and the semiconductor element is mounted, wherein
the first electrode and the fourth electrode are bonded to the die pad, and
the third terminal is connected to the die pad.

11. The semiconductor device according to claim 10, further comprising:
a first conductive plate bonded to the second electrode, and
a second conductive plate bonded to the fourth electrode, wherein
the first conductive plate is bonded to the first terminal, and
the second conductive plate is bonded to the second terminal.

12. The semiconductor device according to claim 9, further comprising:
a first die pad on which the switching element is mounted with the second electrode being bonded to the first die pad; and
a second die pad on which the semiconductor element is mounted with the fifth electrode being bonded to the second die pad, wherein
the first die pad and the second die pad are spaced apart from each other,
the first terminal is connected to the first die pad, and
the second terminal is connected to the second die pad.

13. The semiconductor device according to claim 12, further comprising a conductive plate to which each of the first electrode and the fourth electrode is bonded,
wherein the conductive plate is bonded to the third terminal.

14. The semiconductor device according to claim 2, wherein the sealing resin includes a first resin side surface and a second resin side surface facing away from each other in a first direction orthogonal to the thickness direction,
each of the first terminal and the second terminal is exposed from the first resin side surface, and
the third terminal is exposed from the second resin side surface.

15. The semiconductor device according to claim 14, wherein the plurality of terminals include a fourth terminal electrically conducting to the third electrode.

16. The semiconductor device according to claim 15, wherein the fourth terminal is exposed from the second resin side surface.

17. The semiconductor device according to claim 15, wherein the fourth terminal is exposed from the first resin side surface.

18. The semiconductor device according to claim 1, wherein the switching element is a transistor, and
the semiconductor element is a diode.

19. An electronic device comprising:
the semiconductor device as set forth in claim 1;
a capacitor; and
a mounting substrate on which the semiconductor device and the capacitor are mounted, wherein
the capacitor includes an electrode electrically connected to the first terminal, and
the capacitor includes another electrode electrically connected to the second terminal.

20. The electronic device according to claim 19, further comprising an inductor mounted on the mounting substrate,
wherein the inductor is electrically connected to the third terminal.
